(19) United States
(12) Patent Application Publication
(10) Pub. No.: US 2010/0093022 A1
(43) Pub. Date: Apr. 15, 2010

(54) METHODS AND APPARATUS FOR PROVIDING AND PROCESSING SLICED THIN TISSUE

(76) Inventors: Kenneth Hayworth, Northridge, CA (US); Narayanan Kasthuri, Cambridge, MA (US); Jeff Lichtman, Cambridge, MA (US); Erika Hartwieg, Belmont, MA (US)

Correspondence Address: WOLF GREENFIELD & SACKS, P.C., 600 ATLANTIC AVENUE, BOSTON, MA, 02210-2206, US

(21) Appl. No.: 12/312,832

(22) PCT Filed: Nov. 28, 2007
(86) PCT No.: PCT/US07/24507

§ 371 Date: Dec. 24, 2009

Related U.S. Application Data
(60) Provisional application No. 60/867,487, filed on Nov. 28, 2006.

(51) Int. Cl. G01N 1/30; B26D 5/08; H01J 37/28; G05B 13/02

(52) U.S. Cl. 435/40.52; 83/13; 83/72; 250/311; 700/275

(57) ABSTRACT

Methods and apparatus for providing and processing serial tissue sections. In one example, an “automatic tape collecting lathe ultramicrotome” (ATLUM) slices a block of tissue sample having various geometries into a continuous ribbon of thin tissue, or multiple thin tissue sections, and disposes the sliced thin tissue on an appropriate substrate to facilitate subsequent imaging of the sliced thin tissue. Closed-loop control of section thickness of the sliced thin tissue sections or ribbons is implemented to produce thinner sliced tissue sections or ribbons and tightly regulate thickness. Thin tissue sections or ribbons may be particularly processed/prepared to facilitate imaging with a scanning electron microscope (SEM). Collected thin tissue sections or ribbons may be used to create UltraThin Section Libraries (UTSLs) that allow for fully automated, time-efficient imaging in the SEM to facilitate expansive tissue studies.

### FIELD OF THE INVENTION

The present invention relates generally to automating the process of producing sliced thin tissue from a block of sample tissue block so as to allow the thin tissue to be reliably collected, handled, stored, and digitally imaged (via automated retrieval).

### BACKGROUND

Today neuroscientists are routinely carrying out evermore-advanced physiological experiments and cognitive scientists are proposing and testing evermore-comprehensive models of brain function. Unfortunately, these experiments and models involve brain systems where incomplete information regarding the system's underlying neural circuitry presents one of the largest barriers to research success. It is widely accepted within the neuroscience community that what is needed is a comprehensive and reliable wiring diagram of the brain that will provide a neuroanatomical scaffolding (and a set of foundational constraints) for the rest of experimental and theoretical work in the neuro- and cognitive sciences. Unfortunately, the current approach of attempting to integrate the deluge of thousands of individual in vivo tracing experiments into a coherent whole is proving to be a virtually impossible task.

There is an alternative approach that avoids the problem of stitching together the results of thousands of in vivo tracer injection experiments. The imaging of a single post-mortem brain at a sufficiently high resolution to resolve individual neuronal processes and synapses, while maintaining registration across size-scales, would allow direct tracing of a brain's connectivity. Researchers using the raw data in such a synapse-resolution brain connectivity atlas would be able to map all the regions, axonal pathways, and synaptic circuits of the brain; and unlike separate specialized experiments, the results would immediately and easily be integrated because they are all performed on the same physical brain.

Today, the creation of such a synapse-resolution atlas has only been achieved for tiny invertebrate animals such as C. Elegans (a round worm measuring 1 mm in length and less than 100 um in diameter). This is because the fundamental technology used, that of serial section electron reconstruction, currently requires the painstaking manual production of thousands of extremely thin (<1 μm) tissue slices using a standard ultramicrotome in which newly sliced tissue sections are floated away from the cutting knife on water and manually placed on slotted TEM specimen grids a few sections at a time.

Because of the manual nature of this current process, this technique is totally impractical to apply to larger brain structures and so it is currently unable to address the needs of the larger community of neuroscientists who require a map of the brain connectivity of rodent and primate brains. The key challenge in extending these imaging technologies to map structures that are 1×10⁵ (mouse brain) and 1×10⁸ (human brain) times as large as C.

We are unaware of any current microtome design (either in production or disclosed in the open literature) that adequately addresses this need for automating the production, collection, handling, and imaging of large numbers of thin tissue sections suitable for use in light and transmission electron microscopic 3D reconstruction work. Although there is a vast number of patents pertaining to microtomes and their automation, these designs are targeted toward automating the slicing process only, and do not address the tissue collection and handling processes. Today the term “automated microtome” has become synonymous with a manual microtome merely having motorized knife advance. Thus, current “automated microtome” designs still require manual slice retrieval and manual slide or grid mounting for imaging. Such manual slice retrieval necessitates skilled, delicate, and incredibly time-consuming work be expended on each tissue slice (or small series of slices) as it involves “fishing” each tissue slice out of a water boat attached to the knife of the ultramicrotome instrument and onto a TEM grid.

One published microtome design that does somewhat address the automation of tissue collection is U.S. Pat. No. 5,746,855 by Bolles. In that design, the standard manual method of blockface taping (whose advantages for slice collection and handling are described more fully in U.S. Pat. No. 4,545,831 by Ornstein) is proposed to be automated by a pressure roller pressing a reel of transparent adhesive tape against the blockface just before the microtome blade cuts the next slice of tissue off the block. Thus the slice is adhered to the tape and can be carried away automatically by simply advancing the tape reel. (The advantages of tape as a collection, storage, and imaging medium for tissue sections is described in U.S. Pat. No. 3,939,019 by Pickett.)

Another proposed method for automating the collection of tissues from a microtome disclosed in U.S. Pat. No. 6,387,653 by Voneiff and Gibson, proposed the use of a series of rollers to collect the tissue from the blade of a microtome and move it directly to a glass slide. That design also makes no modification to the current standard microtome design, and thus also suffers from the discontinuous ratcheting action. The Voneiff and Gibson design, however, uses neither blockface taping nor tape as a collection medium.

It should be noted that neither the Bolles' design nor the Voneiff and Gibson design target the collection of tissue slices for electron microscopic (ultrastructure) imaging. Imaging by an electron beam requires that the tissue slice is unobstructed by any holding substrate thicker than a few nanometers. The tape in Bolles' design and the glass slide in the Voneiff and Gibson design are much too thick for this. The design disclosed herein directly targets collection of slices for light and transmission electron microscopic imaging, and makes modifications to the tape collection medium in order to accommodate this.

### SUMMARY OF INVENTION

Various embodiments of the present invention are directed to methods and apparatus for providing and processing serial tissue sections. In exemplary embodiments, an “automatic tape collecting lathe ultramicrotome” (ATLUM) is disclosed, in which the basic ratcheting motion of the microtome is redesigned, replacing the conventional discontinuous ratcheting motion with a continuous rotary Motion of a lathe. Using an ATLUM, a block of tissue sample having various geometries may be sliced into a continuous ribbon Of thin tissue; or multiple thin tissue sections, and disposed on an appropriate substrate to facilitate subsequent imaging of the sliced thin tissue. As will be described in greater detail below, the continuous lathe cutting design makes possible continuous taping and slice collection. The result is a mechanically more stable, more reliable, faster, and more easily constructed design that facilitates fully automated production, collection, handling, imaging, and storage of thousands of semi-thin and ultra-thin tissue sections.

In some inventive embodiments disclosed herein, closed-loop control of section thickness of thin tissue sections or ribbons sliced from a tissue sample is implemented to produce thinner sliced tissue sections or ribbons having tightly controlled thickness. Thinner samples with predictable thickness in turn facilitate high quality volume reconstructions of biological samples. In one exemplary implementation, one or more capacitive sensors are employed in an ATLUM to facilitate regulation of a distance between a slicing knife and a tissue sample to be sliced, thereby controlling sliced tissue thickness with improved precision. Other types of distance sensing techniques may be employed in other implementations to control and regulate sliced tissue thickness.

In yet other inventive embodiments disclosed herein, thin tissue sections or ribbons are particularly processed/prepared to facilitate imaging with a scanning electron microscope (SEM) (e.g., in electron backscatter mode). Imaging via an SEM is generally a significantly simplified process as compared to imaging via a TEM (transmission electron microsope), and images obtained via SEM of sufficient quality, and in many instances equivalent quality, to conventional TEM images. In one aspect of these embodiments, collected tapes of thin tissue sections or ribbons sliced from a tissue sample are used to create UltraThin Section Libraries (UTSLs) that allow for fully automated, time-efficient imaging in the SEM.

In view of the foregoing, aspects of the current invention provide for thinner tissue sections having tightly controlled thickness produced in a fully automated fashion. In exemplary applications made possible by embodiments of the present invention, tens of meters of ultrathin sections may be automatically sliced and collected on a tape that is subsequently stained with heavy metals and mounted onto plates for any appropriate imaging mode in a scanning electron microscope (SEM), such as, but not limited to, electron backscatter imaging. ATLUM-collected sections may provide images equivalent to TEM images, showing detail down to individual synaptic vesicles within synapses. The ATLUM can also quickly create a UTSL of many cubic millimeters of tissue, enough to encompass multiple brain regions and their interconnecting axonal tracts. The UTSL can also be swiftly SEM imaged, and this can be used to intelligently direct subsequent time intensive high-resolution imaging forays. In this manner, researchers may efficiently map out specific neural circuits spanning several millimeters with a resolution in the nanometer range.

In sum, one embodiment of the present invention is directed to a method for preparing and imaging a tissue sample. The method comprises A) slicing the tissue sample into at least one thin tissue section; B) mounting the at least one thin tissue section on to a substrate, the substrate comprising a conductive material; and C) imaging the mounted at least one thin tissue section with a scanning electron microscope.

Another embodiment is directed to a tissue sample prepared for scanning electron microscopy imaging. The tissue sample comprises a substrate comprising a conductive material, and at least one tissue section mounted on to the substrate, the at least one tissue section having a section thickness, the section thickness being less than 500 nanometers.

Another embodiment is directed to a method for preparing a tissue sample. The method comprises: A) slicing the tissue sample in a slicing direction using a microtome knife to provide at least one thin tissue section, the at least one thin tissue section having a section thickness, the section thickness being controlled by an advancement of the microtome knife into the tissue sample in a substantially perpendicular direction relative to the slicing direction; B) monitoring the advancement of the microtome knife into the tissue sample as the tissue sample is being sliced to provide an estimated section thickness; C) comparing the estimated section thickness to a desired thickness; and D) controlling the advancement of the microtome knife into the tissue sample so that a difference between the estimated section thickness and the desired thickness is less than or equal to 20 nanometers.

Another embodiment is directed to a method for preparing a tissue sample. The method comprises: A) slicing the tissue sample into at least one thin tissue section, the at least one thin tissue section having a section thickness; B) monitoring at least one parameter representing the section thickness of the at least one thin tissue section as the tissue sample is sliced to provide an estimated section thickness; C) comparing the estimated section thickness to a desired thickness; and D) controlling slicing the tissue sample into at least one thin tissue section, the at least one thin tissue section having a section thickness such that a difference between the estimated section thickness and the desired thickness is less than or equal to 20 nanometers.

Another embodiment is directed to a microtome system comprising: a rotatable axle adapted to support at least one tissue sample; a moveable stage disposed in proximity to the rotatable axle; a microtome knife coupled to the moveable stage, the moveable stage adapted to position the microtome knife with respect to the rotatable axle so as to provide a first variable distance between the microtome knife and the rotatable axle; at least one sensor, the at least one sensor adapted to measure the variable distance between the microtome knife and the rotatable axle and provide at least one measurement signal; and a controller coupled to the moveable stage and the at least one sensor, the controller configured to monitor the at least one measurement signal and control the moveable stage so as to control the variable distance between the microtome knife and the rotatable axle based at least in part on the at least one measurement signal.

Another embodiment is directed to a method for preparing and imaging tissue samples. The method comprises: A) slicing the tissue sample in a slicing direction using a microtome knife to provide at least one thin tissue section, the at least one thin tissue section having a section thickness, the section thickness being controlled by an advancement of the microtome knife into the tissue sample in a substantially perpendicular direction relative to the slicing direction; B) monitoring the advancement of the microtome knife into the tissue sample as the tissue sample is being sliced to provide an estimated section thickness; C) comparing the estimated section thickness to a desired thickness; D) controlling the advancement of the microtome knife into the tissue sample so that a difference between the estimated section thickness and the desired thickness is less than or equal to 20 nanometers; E) mounting the at least one thin tissue section on to a substrate, the substrate comprising a conductive material; and F) imaging the mounted at least one thin tissue section with a scanning electron microscope.

The following applications are incorporated herein by reference: U.S. non-provisional application Ser. No. 10/886,799, filed Jul. 8, 2004, entitled “Methods and apparatuses for the automated production, collection, handling, and imaging of large numbers of serial tissue sections,” and U.S. provisional application Ser. No. 60/867,487, filed Nov. 28, 2006, entitled “Methods and Apparatus for Providing and Processing Serial Tissue Sections.”

It should be appreciated that all combinations of the foregoing concepts and additional concepts discussed in greater detail below are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

In all drawings like reference numbers represent corresponding parts throughout:

FIG. 1A is a perspective view of the bottom silicone rubber mold.

FIG. 1B is a perspective view of the toothed silicone rubber mold.

FIGS. 1C, 1D, and 1E are a series of perspective views showing the first three sequential steps in the tissue embedding process.

FIG. 2A is a close-up view of the tooth-indentation cavities.

FIG. 2B is a close-up view of tissue cubes being placed in the tooth-indentation cavities.

FIG. 2C is a perspective view of the top silicone rubber mold.

FIGS. 2D, 2E, and 2F are a series of perspective views showing the fourth, fifth, and sixth steps in the tissue embedding process.

FIGS. 3A and 3B are perspective views showing the last two steps in the tissue embedding process.

FIG. 3C is an enlarged view of the final cured axle-mounted cylindrical tissue block.

FIG. 3D is a view showing where the axle-mounted tissue block gets inserted in the automatic taping lathe-microtome.

FIG. 4A is a perspective view showing one embodiment of the automatic taping lathe-microtome. The supporting housing of the taping mechanism is removed in this and following figures to better display the mechanism.

FIG. 4B is a close-up view of where the knife cuts the tissue block in the automatic taping lathe-microtome.

FIG. 5A is a perspective view detailing the tape-web mechanism and cylindrical tissue block (with lathe body removed).

FIG. 5B is a close-up view from the back of the tissue block. This view details the blockface applicator mechanisms.

FIG. 5C is a close-up view of the side of the tissue block during operation of the automatic taping lathe-microtome.

FIG. 6A is a perspective view of the final composite tape sandwich, where each layer in the composite sandwich is peeled away and labeled.

FIG. 6B is a view of the final composite tape sandwich from the underside.

FIG. 7A is a perspective view showing the electron tomography tape cassette with side panels removed to reveal the tissue tape reels within.

FIG. 7B is a close-up view of the specimen stage tip of the electron tomography tape cassette.

FIG. 7C is a close-up view of the specimen stage tip of the electron tomography tape cassette where the sides of the tip have been removed to reveal the tape path and clamping mechanism within.

FIG. 8A is a perspective view of the electron tomography tape cassette with arrows drawn to display the main degrees of freedom of movement allowed by the mechanism.

FIG. 8B depicts a stylized transmission electron microscope (TEM) with the electron tomography tape cassette inserted into its specimen port.

FIGS. 8C, 8D, and 8E are three close-up views of the electron tomography tape cassette detailing how the entire cassette mechanism can rotate relative to the TEM in order to perform a tomographic tilt-series on the tissue sample at the tip.

FIG. 9A is a schematic side view of alternative embodiment #1.

FIG. 9B is a schematic side view of alternative embodiment #2.

FIG. 9C is a schematic side view of alternative embodiment #3.

FIG. 9D is a schematic side view of alternative embodiment #4.

FIG. 9E is a schematic side view of one embodiment.

FIG. 10A is a front plan view of a nanosectioning lathe ultramicrotome according to an embodiment of the present invention;

FIG. 10B is a perspective view of a nanosectioning lathe ultramicrotome according to an embodiment of the present invention;

FIG. 11 is a close up perspective view of a knife stage, tissue axle, and conveyor belt collection mechanism according to an embodiment of the present invention;

FIG. 12A is a side plan view of a nanosectioning lathe ultramicrotome without the sensors according to an embodiment of the present invention;

FIG. 12B is a side plan view of a nanosectioning lathe ultramicrotome with a sensor and PID feedback mechanism according to an embodiment of the present invention;

FIG. 13A is a side plan view of a nanosectioning lathe ultramicrotome with a conveyor belt mechanism according to an embodiment of the present invention;

FIG. 13B is a side plan view of a nanosectioning lathe ultramicrotome with a conveyor belt mechanism in operation according to an embodiment of the present invention;

FIG. 14A is a side plan view of a nanosectioning lathe ultramicrotome with a conveyor belt mechanism in operation where the thin tissue section is continuously sliced according to an embodiment of the present invention;

FIG. 14B is a side plan view of a nanosectioning lathe ultramicrotome with a conveyor belt mechanism in operation where the thin tissue section length is shorter than the distance from the knife edge to the conveyor belt according to an embodiment of the present invention;

FIG. 14C is a side plan view of a nanosectioning lathe ultramicrotome with a conveyor belt mechanism in operation where the thin tissue section length is longer than the distance from the knife edge to the conveyor belt according to an embodiment of the present invention; and

FIG. 15 is a nanosectioning lathe ultramicrotome knife stage control diagram according to an embodiment of the present invention.

### DETAILED DESCRIPTION

Following below are more detailed descriptions of various concepts related to, and inventive embodiments of, methods and apparatus according to the present disclosure for providing and processing sliced thin tissue. It should be appreciated that various aspects of the subject matter introduced above and discussed in greater detail below may be implemented in any of numerous ways, as the subject matter is not limited to any particular manner of implementation. Examples of specific implementations and applications are provided primarily for illustrative purposes.

One embodiment of the present invention discloses a device, an automated tape collecting lathe-ultramicrotome (“ATLUM”), and associated methods and apparatus for fully automating the collection, handling, and imaging of large numbers of serial tissue sections.

Classical TEM tissue processing and imaging methods begin by embedding an approximately 1 mm³ piece of biological tissue that has been fixed with mixed aldehydes, post-fixed with osmium tetroxide, and infiltrated with an embedding resin. This single tissue cube is then placed in a silicone rubber mold which is then filled with liquid embedding resin. The mold is placed in an oven in order to cure the resin and tissue into a hard tissue block. This tissue block is then clamped in the chuck of a microtome (for TEM use this is also called an ultramicrotome).

This chuck is mechanically actuated to allow the tissue block to be driven down in a smooth trajectory across a very sharp knife thus liberating a slice of the embedded tissue suitably thinned to allow TEM imaging. In “sliding” and “rotary” microtome designs the chuck is moved along a linear trajectory across the blade. (The rotation in a “rotary” microtome is referring to a crank wheel that is rotated by the operator. That rotation is converted to a linear motion of the chuck.) In a “disc” microtome (see U.S. Pat. No. 6,253,653) the trajectory of chuck movement is along a circular arc; however, the sliding, rotary, and disc microtomes' motions are all inherently saltatory using a discontinuous ratcheting motion where the knife engages and disengages the tissue block every slice. Sequential tissue sections are produced by ratcheting the chuck forward toward the knife a small distance after each slice.

The resulting thin tissue slices are typically less than 1 μm thick and are extremely fragile. In fact, they are so fragile that they would be destroyed if one attempted to remove them from the bare surface of the knife which produced them. For this reason, the knife has a boat of water attached to it in such a manner as to allow newly cut tissue to float on the water (supported by surface tension) immediately subsequent to its cutting from the tissue block. This technique protects the fragile tissue section from friction induced mechanical damage which would occur from extended contact with the knife's body. A histology technician then manually scoops the floating tissue section (or short series of sections) onto a slotted TEM specimen grid, one whose slot opening has been previously coated with an ultra-thin film of plastic TEM support film. This support film is strong enough to provide support for the tissue section bridging the slot's gap, but still thin enough to allow unobstructed TEM viewing.

To image this tissue section, the specimen grid is placed in a TEM specimen stage and manually inserted into the vacuum port of a TEM. Vacuum is pulled on the TEM, and the specimen is finally imaged via the TEM's electron beam. Reliably producing, collecting, and imaging thousands of serial sections from a single block is required to reconstruct even cubic millimeter-sized volumes of neural tissue, and this is virtually impossible to accomplish using these classical methods and microtome designs.

The innovations disclosed here are designed to bring a high degree of automation to this entire process of tissue collection, handling, and imaging; thus allowing the mass production of serial sections for large-volume 3D reconstruction research. This automated mass production is accomplished by the following innovations to the classical methods and microtome designs:
a. Innovation #1: Embed multiple tissue cubes in a single block and process them all at the same time.
b. Innovation #2: Use an axle-mounted cylindrical tissue block and continuous lathe slicing motion (instead of the traditional discontinuous ratcheting motion of current sliding, rotary, and disc microtome designs).
c. Innovation #3: Strengthen the tissue sections before cutting by use of blockface thinfilm deposition and blockface taping, thus making subsequent steps more reliable.
d. Innovation #4: Collect tissue sections by the thousands via a tape-sandwich that doubles as a durable handling and storage medium, as well as a TEM imaging specimen grid.
e. Innovation #5: Load entire tissue-tape (containing thousands, of serial sections) into the electron microscope all at once, threading the tape through the electron beam in a fashion similar to film in a movie projector. This allows random-access imaging of any tissue section on the entire tape without forfeiting the time needed to crack the TEM's vacuum and re-pumping.

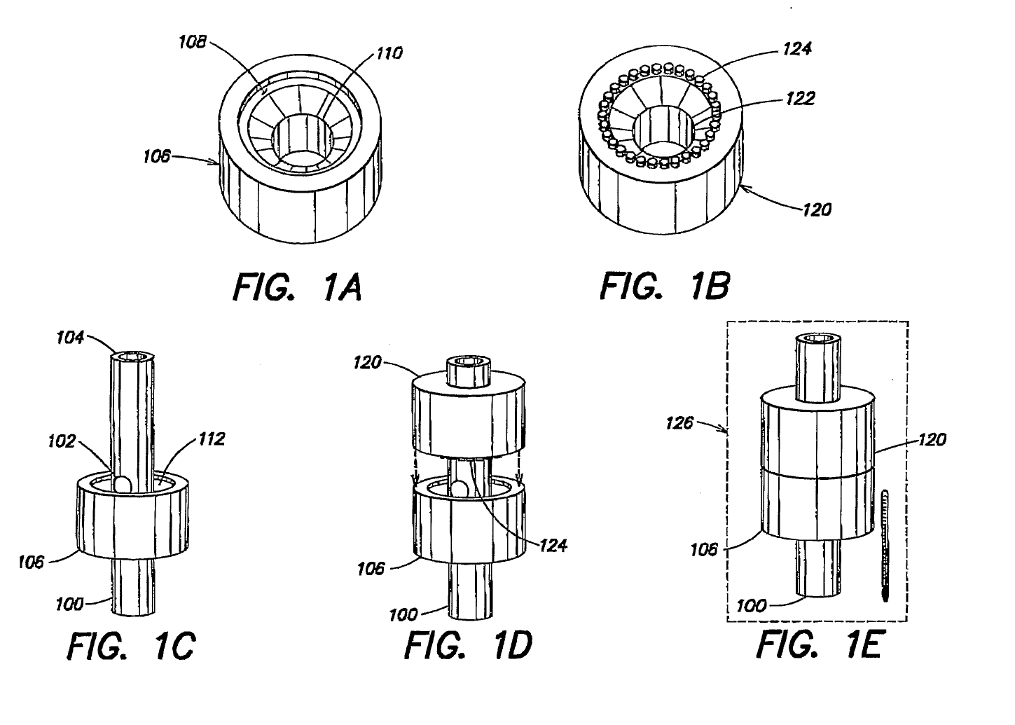

FIG. 1A shows a silicone rubber embedding mold 106, having a cylindrical cavity 108, and a central hole 110. FIG. 1C shows how the mold 106 is slipped onto a metal axle 100 such that the hole 108 forms a liquid-tight seal against the axle 100. The axle 100 has center-drilled ends 104 for eventual mounting on a lathe. In the first step of the embedding process depicted in FIG. 1C, liquid embedding resin 112 is poured into mold 106 to fill it halfway. The axle 100 has a central hole 102 which is also filled by the resin 112.

FIG. 1B shows a toothed silicone rubber mold 120. This mold also has a central hole 122 which forms a seal with the axle 100. The toothed silicone rubber mold 120 has a multitude of protruding teeth 124. FIG. 1D depicts the second step of the embedding process. The toothed silicone rubber mold 120 is slipped onto the top of the axle 100 such that the teeth 124 become immersed a set distance into the liquid embedding resin 112. A repeatable depth of immersion of the teeth 124 into the resin 112 is guaranteed when the toothed mold 120 is pressed against the bottom mold 106 such that they form a tight seal.

FIG. 1E depicts the third step of the embedding process. The axle 100 with filled molds 106 and 120 are placed in a curing oven schematically depicted by a rectangle and thermometer symbol 126. The axle is left in the oven until the resin is partially cured.

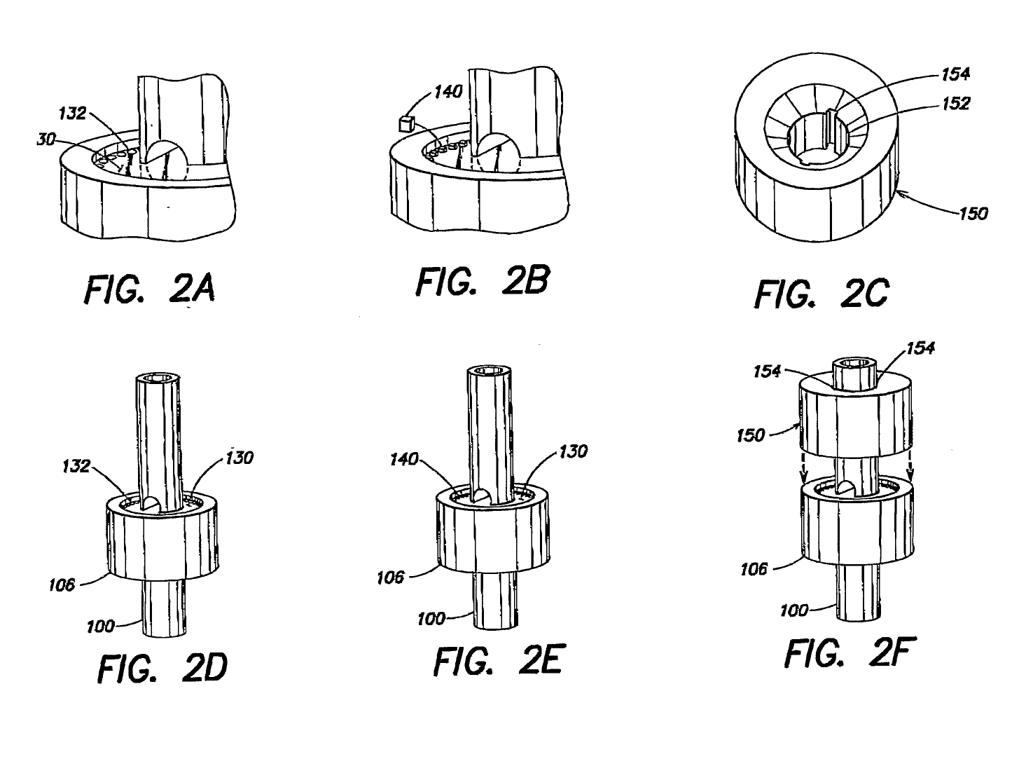

FIG. 2A (close-up) and FIG. 2D depict the fourth step of the embedding process where the toothed mold 120 is removed after curing to reveal a partially cured embedding resin 130 having a multitude (count of 30) of tooth-indentation cavities 132. In FIG. 2B (close-up) and FIG. 2E, the fifth step of the embedding process, a multitude of tissue cubes 140 are manually placed into some, but not all, of the tooth-indentation cavities 132. A total of 27 tissue cubes are inserted into the tooth-indentation cavities leaving three cavities free of tissue. Each of these tissue cubes 140 have been previously been fixed with mixed-aldehydes, post-fixed with osmium tetroxide, en bloc stained with heavy metals, and infiltrated with resin as per standard TEM tissue processing procedures. The tooth-indentation cavities 132 provide a means to secure the tissue cubes 140 in a set orientation and position with respect to each other and to the axle 100 throughout the rest of the embedding process.

FIG. 2C shows a silicone rubber top mold 150. This mold is also designed to slip onto axle 100 via a hole 152 in the center of the mold 150. Two resin fill-ports 154 ensure that the hole 152 does not make a complete seal with the axle 100, but instead leaves a path for resin filling.

FIG. 2F depicts the sixth step of the embedding process where the top mold 150 is slipped onto axle 100 and pressed into contact with bottom mold 106 such that the two form a liquid-tight seal against each other. Thus they together form a single tissue embedding mold cavity.

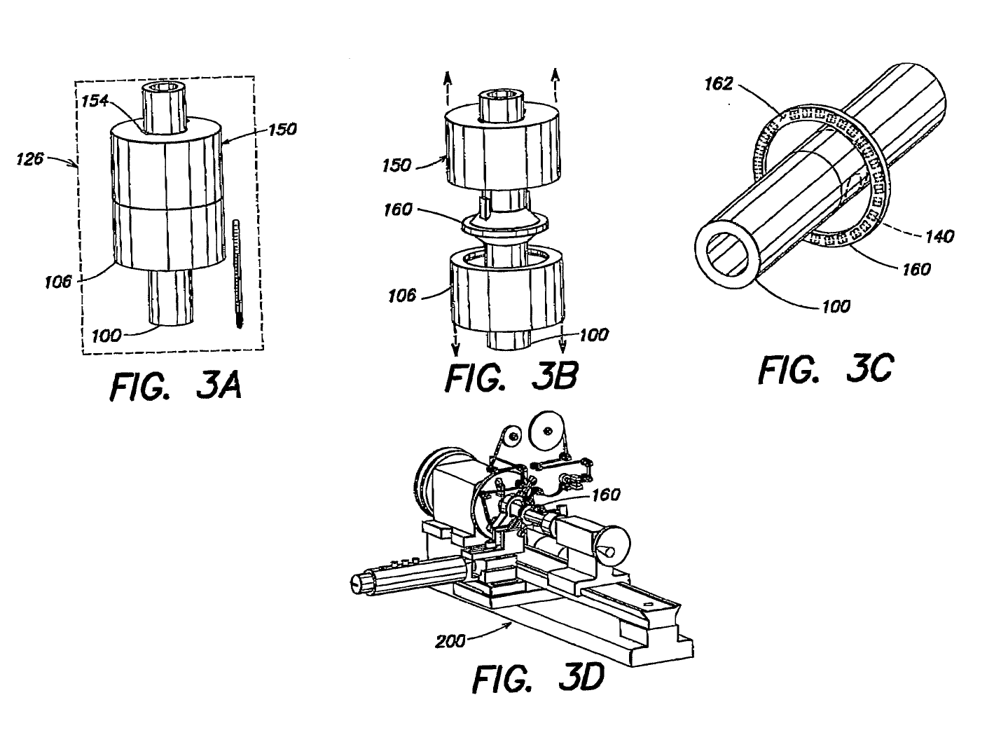

In step seven of the embedding process, depicted in FIG. 3A, new liquid resin is poured into one of the resin fill-ports 154 and air is allowed to escape through the other fill-port 154. Enough resin is poured in to fill up the entire cavity of molds 106 and 150. This assembly of axle 100 is then placed in curing oven 126 and allowed to completely cure. Removal of the top mold 150 and the bottom mold 106 is depicted in FIG. 3B. This reveals a completely cured axle-mounted cylindrical tissue block 160. If necessary, excess pieces of cured resin or inaccuracies in block shape can be removed or corrected by lathing down the sides of the axle-mounted cured cylindrical tissue block 160 at this step using a standard commercial lathe.

FIG. 3C show a more detailed view of the axle-mounted cylindrical tissue block 160. The 27 embedded tissue cubes 140 are seen populating the circumference of the cylindrical tissue block. Three empty spots in this circumference 162 are also depicted (these empty positions along the circumference will be used later for “blowout hole” slots needed during the imaging processes). The automatic taping lathe-microtome described next will shave a thin spiral ribbon off the circumference of this block and mount that ribbon between protective base tapes. Every full rotation of the axle-mounted tissue block 160 within the automatic taping lathe-microtome will liberate a short stretch of ribbon containing 27 slices of the tissue cubes embedded within. A few thousands of revolutions will liberate a very long ribbon, and will have succeeded in reducing all 27 1 mm³ tissue cubes into a tape containing thousands of thin tissue slices suitable for light or TEM imaging and 3D reconstruction work.

In FIG. 3D shows the position where the axle-mounted cylindrical tissue block 160 is mounted within the automatic taping lathe microtome 200:

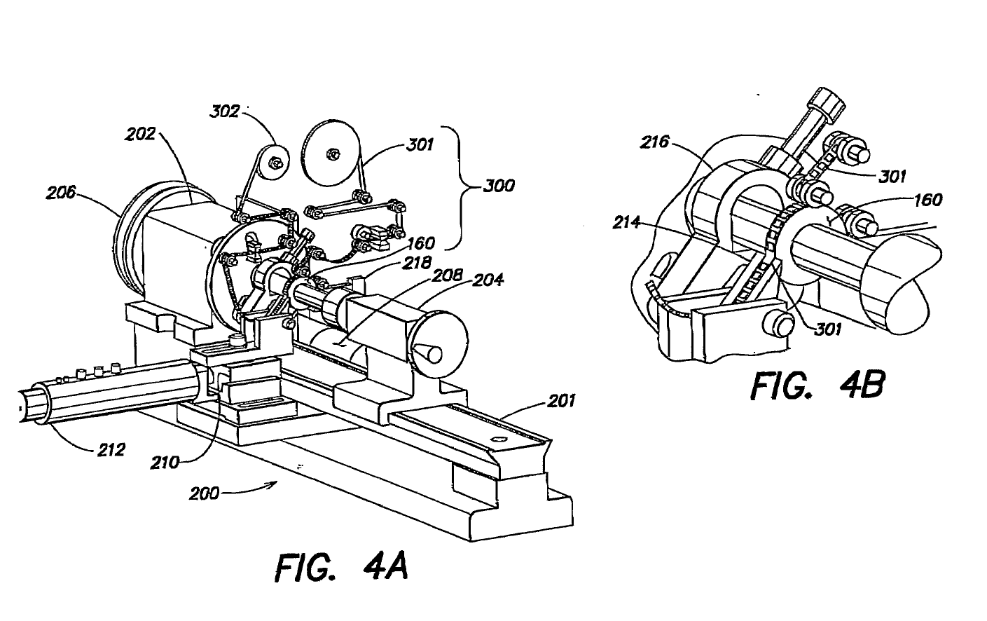

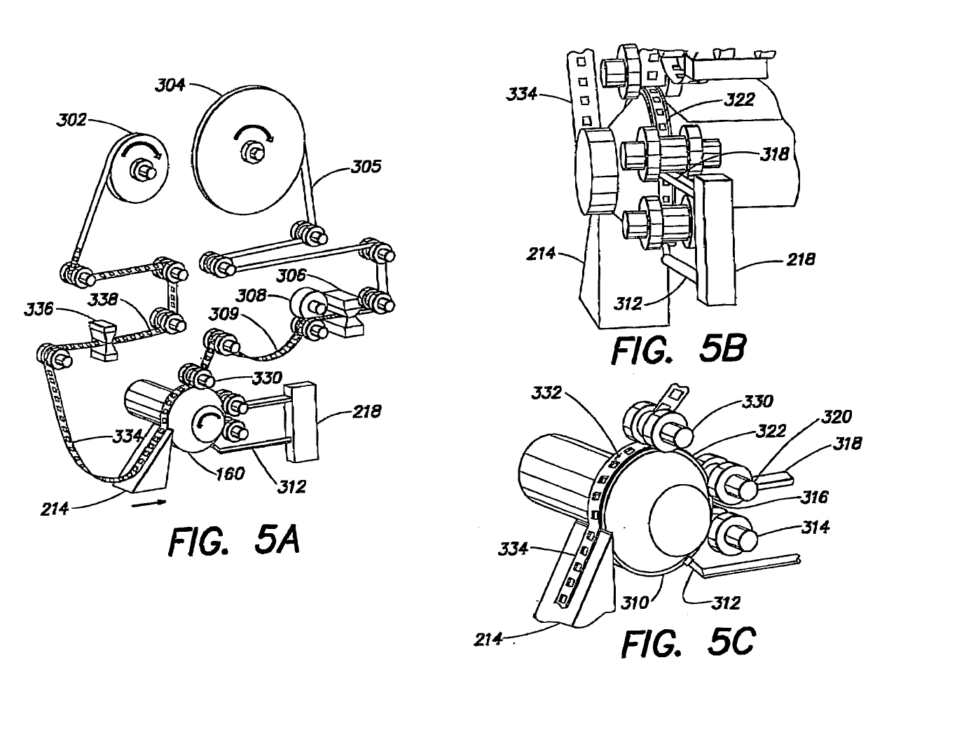

FIG. 4A is a perspective drawing of the automatic taping lathe-microtome 200 depicting all of its main component parts except those associated with the tape-web assembly 300 which is detailed later in FIG. 5A. FIG. 4B is a close-up view of the microtome knife 214 cutting the axle-mounted cylindrical tissue block 160. The main body of the automatic taping lathe-microtome 200 is a small jeweler's lathe 201 having a standard headstock spindle bearing 202, and tailstock with live center 204. The axle-mounted cylindrical tissue block 160 is mounted between the headstock spindle bearing 202 and the tailstock 204 using the center-drilled ends 104 of axle 100. A lathe dog 216 is attached to the axle 100 of the cylindrical tissue block 160 such that the lathe spindle and belt drive 206 can drive the axle-mounted cylindrical tissue block 160 in a rotary motion. The lathe spindle and belt drive 206 is driven by a precision DC gearhead motor 208 at a slow and steady rate setting the pace of the rest of the automatic taping lathe-microtome's mechanisms.

On the side of the lathe body 201 the standard lathe cross-slide has been replaced by a precision linear translation stage 210. This stage is driven by a precision linear motorized actuator 212 which is capable of providing the sub-micron movements necessary for TEM microtomy. Attached to the linear translation stage 210 is the microtome knife 214. This assembly enables the knife 214 to be slowly pressed against the rotating cylindrical tissue block 160 in a lathe-like fashion thus liberating a ribbon of tissue into the tape-web assembly 300. The tape-web assembly 300 holds the tape 301 inline with the rotating cylindrical tissue block 160 such that blockface taping can proceed at a continuous rate in synchrony with the continuous lathe-like cutting of the rotating cylindrical tissue block 160. This continuous blockface taping process will be detailed below. Also shown in FIG. 4A is a thin-film and adhesive blockface-application mechanism 218. This mechanism applies a thin-film coating onto the freshly cut surface of the cylindrical tissue block 160 and then applies two strips of adhesive to the tissue block 160's surface as well. This adhesive is what will secure the tape to the blockface just prior to slicing at knife 214. Final TEM-ready tissue tape is reeled up onto a take-up reel 302.

FIG. 5A is a perspective view detailing the tape-web mechanism 300 and cylindrical tissue block 160 only. The lathe body and cross-slide components have been removed for clarity. FIG. 5B shows the same mechanism, but a close-up view from behind the tissue block detailing the blockface application mechanism. FIG. 5C is a close-up view of the side of the tissue block during operation.

Starting at the top of the Mechanism, a top base tape feed roll 304 supplies a continuous stream of plastic tape 305 into the mechanism. A tape hole puncher mechanism 306 punches square viewing holes into the plastic top base tape 305. The tape is driven forward by tape drive rollers 308 which maintain a slack (no tension) region 309 in the web. This slack region assures that no tension forces from the tape disturb the motion of the cylindrical tissue block 160 or the blockfack taping process.

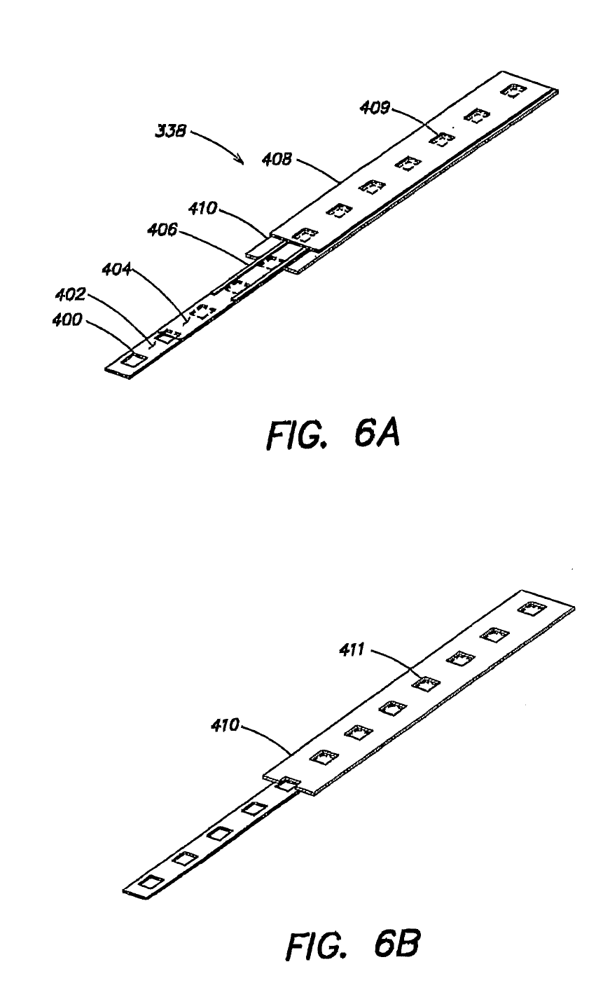

The slack, hole-cut tape 309 is adhered to the block 160's surface at a blockface taping pressure roller 330. The timing of the hole cutting performed by the tape hole puncher mechanism 306 is synchronized to the current angle of the cylindrical tissue block 160 such that each hole will be precisely aligned directly over an embedded tissue cube 140 when the tape 309 is adhered to the block 160. A section 332 of top base tape is adhered for a quarter-turn of the block 160 before it is sliced off the block 160 at the knife 214 along with a thin ribbon 402 (detailed in FIG. 6A) of the tissue block 160. The thickness of this ribbon of tissue is set by the relative rotary speed of the lathe spindle 206 and the linear speed of the knife 214. Both speeds are constant and serve to cut off a continuous spiral ribbon of embedded tissue 402 which is already adhered to the tape 332 at the time of cutting producing a freshly microtomed ribbon of tissue adhered to top base tape 334.

The ribbon of tissue adhered to tape 334 is reeled up by a final composite tissue tape-sandwich take-up reel 302, but before it gets there the tape 334 is driven past a bottom base tape applicator (and blowout hole mechanism) 336 that applies (prints) a covering bottom base tape 410 (detailed in FIG. 6A). The blowout hole function of 336 will be discussed later during the section on tape imaging. This produces a TEM-ready composite tape sandwich (abbreviated tissue-tape) 338 which is reeled up onto take-up reel 302.

FIGS. 5B and 5C more clearly show the blockface preparation steps leading up to the production of the adhered section of tape 332. The freshly cut surface of cylindrical tissue block 310 comes into contact with the TEM support film head 312 which lays down a thin-film on the entire surface of the block with the help of a smoothing and drying roller mechanism 314. This produces a support film coated block surface 316. This surface next comes in contact with two adhesive strip applicator heads 318 that, with the help of a smoothing and drying roller mechanism 320, lay down two strips of adhesive on the block face 322. This section of the block's surface with TEM support film and adhesive strips applied is now ready to accept the hole-cut tape 309 for blockface taping via the pressure roller 330.

FIG. 6A shows the composition of the tissue-tape 338. FIG. 6B shows the backside of the tissue-tape. In these figures, each layer in the composite sandwich has been peeled away and labeled. The tissue tape 338 includes a composite tape-sandwich where the microtomed ribbon cut off the tissue block 402 is secured and protected between top 408 and bottom 410 base tapes. A multitude of 1 mm² microtomed tissue slices 400 (each 100 nm to 1 μm thick) are seen to be embedded in the ribbon 402. Further, this ribbon 402 is covered by a TEM support film coating 404 providing support for each tissue slice 400 across the viewing slots (holes) in tapes 408 and 410 (these holes are labeled 409 in the top tape FIG. 6A, and 411 in the bottom tape FIG. 6B). The adhesive strips 406 laid down by the applicator heads 318 just before blockface taping by pressure roller 330 are seen clearly in FIG. 6A. Notice how these strips avoid obstructing the view of the tissue slices 400 but still provide adherence between the tissue ribbon 402 and the top tape 408.

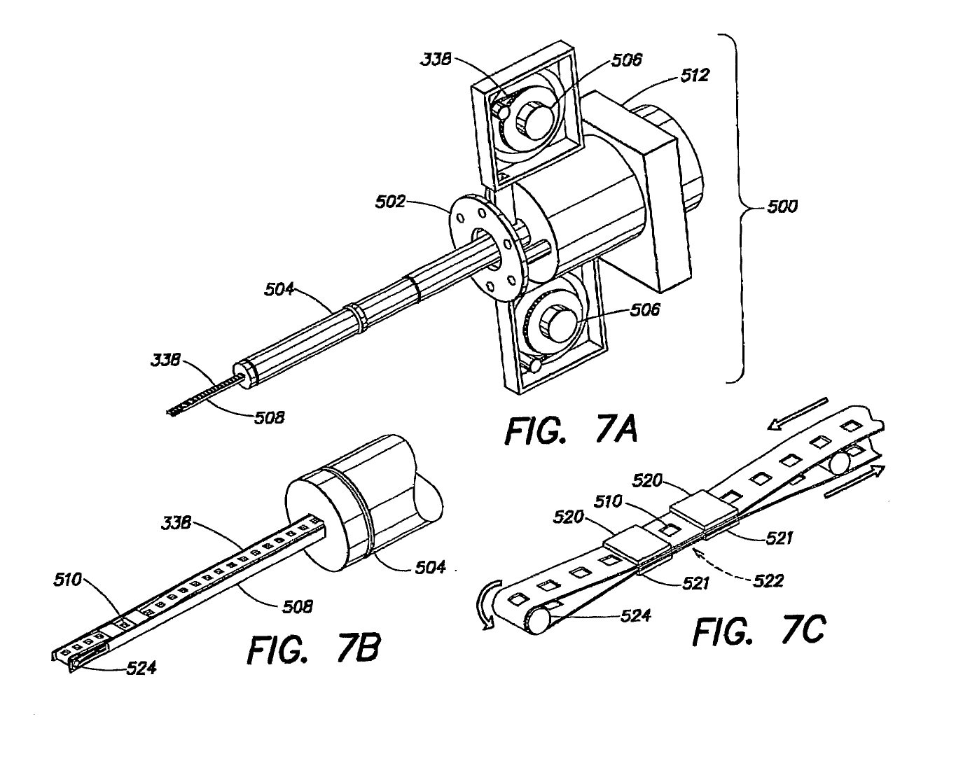

Seen in the close up view offered by FIG. 6A, one can appreciate the tissue-tape 338's similarity to the film in a movie projector. Each tissue slice 400 resides in its own frame, acting as a TEM slot grid. This analogy to the film in a movie projector can be taken further. In this form, the tissue-tape 338 can be reeled up without damage to the delicate tissue slices 400 since the slices are protected on both sides by the base tapes 408 and 410. These reels of tissue-tape can be handled and stored efficiently, and can be fed into an electron tomography tape cassette 500 (shown in FIG. 7A) for fast random access ultrastructure imaging in a standard commercial TEM.

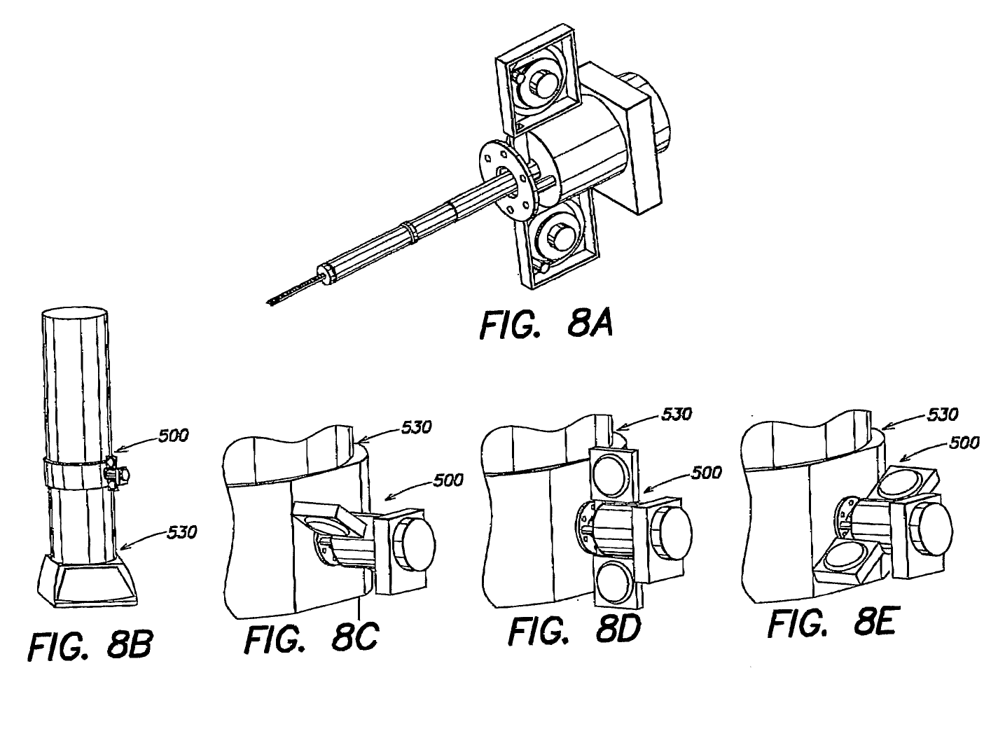

FIG. 7A shows the electron tomography tape cassette 500. Side panels have been removed to reveal two tissue-tape reels 506. The electron tomography tape cassette 500 is designed to act like a standard TEM specimen stage, and thus can slide into the specimen port of a standard TEM 530 (see FIG. 8B). The main difference between the electron tomography tape cassette and a traditional TEM specimen stage is the addition of a set of tape reels and motors 506 for mounting the tissue tape 338 on, and the addition of internal mechanisms that allow the tissue tape 338 to be feed all the way out to the specimen stage's tip 508 and thus into the TEM's electron beam for ultrastructure imaging of the tissue slice 510 clamped at the stage's tip 508. There is a TEM mounting flange 502 which secures the body of the electron tomography tape cassette 500 to the side of a TEM 530. There is also a cylindrical specimen stage body 504 which slips into the vacuum port on the TEM 530 and forms a tight vacuum seal with it, yet simultaneously allows rotation around the long axis of the cylindrical specimen stage body 504. This rotation allows the incidence angle at which the electron beam impinges upon the tissue slice 510 to be varied by rotating the entire assembly of the cylindrical specimen stage body 504 and the cassette reels and motors 506 relative to the mounting flange 502 (see FIGS. 8C, 8D, and 8E). This rotation of the cylindrical specimen stage body 504 relative to the flange 502 is driven by a drive motor 512. Changing this angle of incidence allows for 3D reconstruction of the tissue slice having better resolution in depth than the slice thickness would allow if only 2D (non-tilt series) imaging were performed, and is a standard technique in electron microscopy today.

FIG. 7B shows a close-up view of the specimen stage tip 508. FIG. 7C is a close-up view of the specimen stage tip 508 where the sides of the tip have been removed to reveal the tape path and clamping mechanism within. The tissue-tape 338 wraps around a pulley 524 at the very front of the tip 508. During operation, the tape drive motors 506 reel the tissue tape 338 such that the tissue slice to be imaged 510 is centered between two top clamps 520 and is thus inline with the TEM's electron beam. These two top clamps 520 then engage, securing that section of tissue-tape containing the slice to be imaged 510 stably in position. The pulley 524's position is then adjusted electronically to lengthen or shorten the section of tape 338 between the top clamps 520 and a pair of bottom clamps 521 in order to bring a blowout hole 522 into position between the two bottom clamps 521. These bottom clamps 521 are then engaged to secure the entire tape 338 for imaging.

This blowout hole 522 is one of a multitude of blowout holes spaced periodically throughout the tape 338. These holes are made within the automatic taping lathe microtome's bottom tape applicator and blowout hole mechanism 336 by simply directing a puff of air at the fragile section of sliced ribbon 402 in periodically spaced frames of the tissue tape 338. Recall that a few tooth-indentation cavities 132 are specifically left empty of tissue cubes 140 during the embedding process for this reason. Thus, the final axle-mounted tissue block 160 had three tissue-free regions 162 around its periphery (see FIG. 3C). These holes 522 are purposely blown out to allow the wrapped around section of the tissue tape 338 which resides between the bottom clamps 521 to not obstruct the imaging of the tissue slice 510 directly above it. The cutaway view of the specimen stage tip 508 in FIG. 7C shows both sets of clamps 520 and 521 engaged securely holding a single slice of tissue 510 in position inline with the TEM's electron beam. Directly below this tissue slice 510 is a blowout hole 522 in the tissue tape 338 and thus only the particular slice to be imaged 510 will be seen by the TEM's electron beam.

FIG. 8A shows the electron tomography tape cassette 500 with arrows drawn to display the main degrees of freedom of movement allowed by the mechanism. The reels of tissue tape 506 can rotate in synchrony to bring any desired slice of tissue in the tape out to the specimen tip and thus into the electron beam for imaging. Exact positioning of the field of view is set by driving the whole tip mechanism along the two degrees of freedom perpendicular to the electron beam's cavity (depicted by arrows shown near tip). Also, the entire cassette and stage body 504 can rotate relative to the TEM mounting flange 502 as described below.

FIG. 8B depicts a stylized transmission electron microscope (TEM) with the electron tomography tape cassette inserted into its specimen port. The tape cassette (with cassette covers, which were removed in previous view, installed) is hermetically sealed and can thus share the TEM's vacuum via its seal along the stage's body 504. The tissue tape 338 within the tape cassette 500 is electronically advanced using reel motors 506 to bring a particular tissue slice 510 to be imaged inline with the TEM's electron beam. Clamps (520 and 521) engage to allow stable unobstructed viewing of the slice 510. Any X-Y motions of the stage are now performed to address a small section within the slice (using standard X-Y specimen stage motors present in the electron tomography tape cassette 500 but, for clarity, not depicted here). A tomographic tilt-series (a set of 121 2D electron micrograph images of the tissue slice 510) can be taken by stepping the incidence angle in 1° increments from −60° to +60°.

In FIGS. 8C, 8D, and 8E the manner in which the body of the electron tomography tape cassette rotates relative to the TEM mounting flange 502 is depicted. Those three figures show the tape cassette mechanism at three different incidence angles (−60°, 0°, and +60° respectively).

At each angle, a 2D electron micrograph is produced and all 121 of these images are fed into a standard electron tomographic volume reconstruction algorithm in order to compute a 3D voxel volume digital image of the particular piece of tissue 510 under examination. The system is designed such that any of the multitude of tissue slices in the tissue-tape 338 loaded into the electron tomography tape cassette 500 can be randomly and automatically accessed for 2D or 3D tomographic imaging (at ultrastructure resolution) without ever cracking the vacuum of the TEM. Thus, this avoids any time-consuming manual intervention in the imaging process.

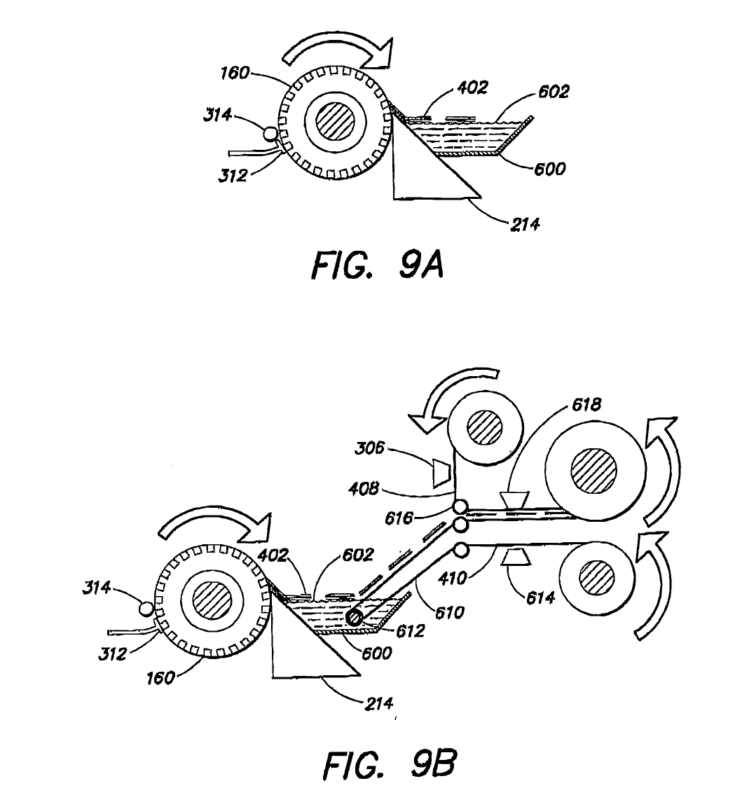

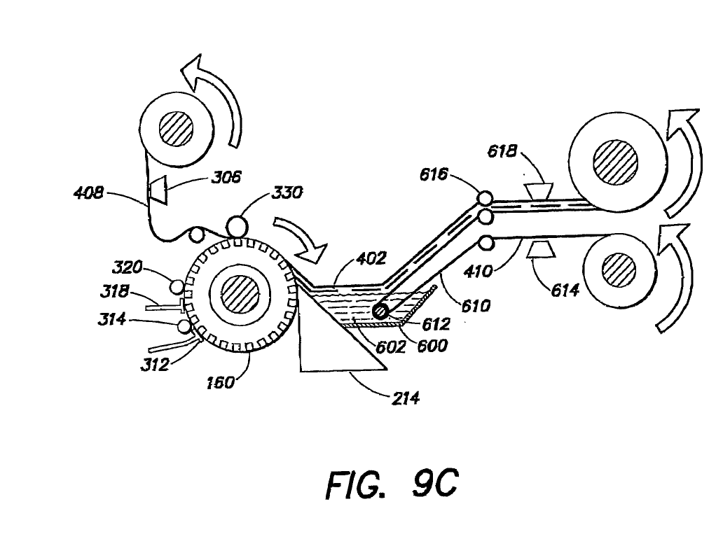

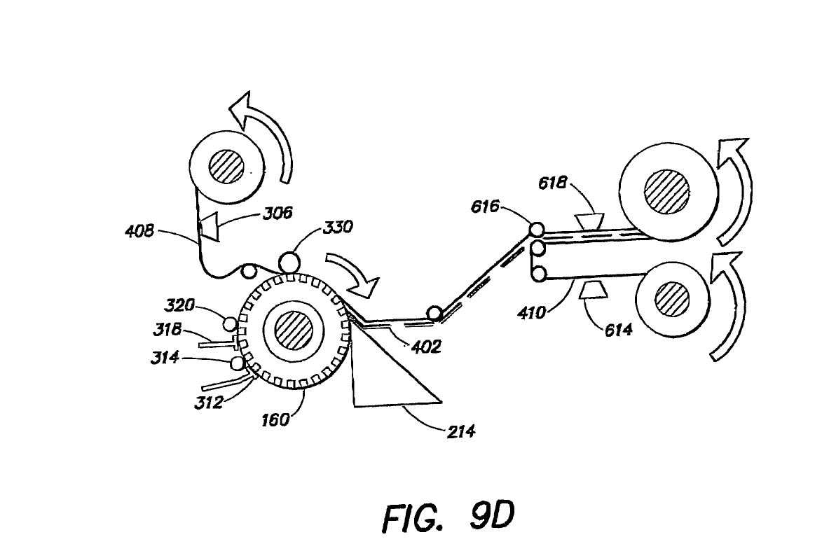

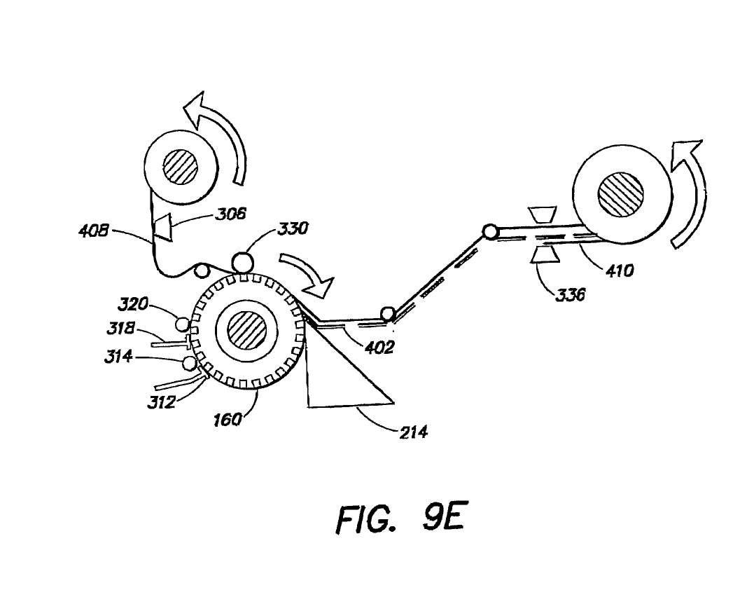

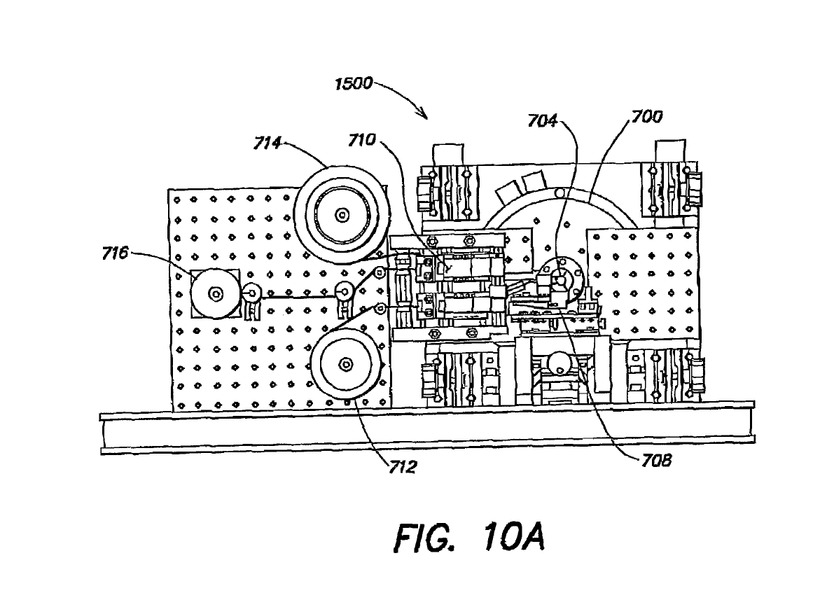

The following describes some alternative embodiments for the automatic taping lathe-microtome. The following descriptions of alternative embodiments of the invention are presented for the purposes of illustration and description. They are not intended to exhaustive or to limit the invention to the precise form disclosed. Some of these alternative designs involve variations on the blockface taping and tissue collection processes, as depicted in a series of schematic side views in FIGS. 9A through 9D. The previously disclosed embodiment is re-represented in FIG. 9E in this same schematic form to further promote ease of comparison.

FIG. 9A shows a minimalist core design (alternative design #1) of the lathe-microtome. The axle-mounted cylindrical tissue block 160 is rotated against the knife 214 in order to liberate a thin ribbon of tissue slices in embedding medium 402. There is no blockface taping in this design (just thin-film support film deposition by 312 and 314) and so a boat 600 filled with water 602 must be attached to the knife 214 in order to collect the fragile un-taped tissue ribbon 402 as it comes off the knife. In this design, once the tissue ribbon becomes longer than the water boat, manual collection of the tissue ribbon is required, thus this design cannot be considered truly automated.

FIG. 9B show alternative design #2. This is a modification to the minimalist core design in which a submerged conveyor belt 610 is made up of the bottom base tape 410 looped around a pulley 612 firmly attached to the knife's water boat and submerged in its water 602. This arrangement allows the fragile floating tissue ribbon 402 to be gently and continuously lifted out of the water by the conveyor belt 610 as shown in the figure. A bottom base tape hole punching mechanism 614 punches viewing holes in the bottom base tape, and its punches are synchronized with the angle of the tissue block 160 such that each tissue slice 400 in the tissue ribbon 402 resides over a viewing hole. The top tape 408 after having similar viewing holes punched in it by hole puncher 306 is aligned and pressed onto the top of the conveyor belt by pressure roller 616. This produces a tape-sandwich which can be sealed by a sealing mechanism (e.g. a heated pressure roller) 618 before finally being reeled up as a finished TEM-ready tissue tape. This design is fully automated and produces a tissue tape-sandwich capable of automated imaging using the electron tomography tape cassette 500. This design (FIG. 9B) does not employ blockface taping meaning that there is a place in the mechanism where a fragile, freely-floating, ribbon of tissue 402 is unsecured by any base tape. This reduces the reliability of the design, but it also reduces its complexity by eliminating blockface taping.

FIG. 9C shows alternative design #3 which simply adds blockface taping to the submerged conveyor-belt design. This design is similar to the previously disclosed embodiement's in its use of a blockface taping pressure roller 330 adhering the top base tape 408 directly to the blockface before cutting. In this way there is never a fragile, unsupported tissue ribbon. This design has both the advantage of blockface taping tissue support at the knife and the advantage of a knife water boat to prevent friction-induced damage with the knife. It, however, suffers from the complexity of both a water boat and blockface taping mechanism.

FIG. 9D shows alternative design #4 in which the water boat has been removed and the conveyor-belt formed by the bottom base tape is no longer submerged. The blockface taping has provided enough support for the tissue ribbon 402 coming off the knife 214 such that the water boat support can be eliminated.

Finally, FIG. 9E shows the previously disclosed embodiment in the same schematic manner as the just described alternative designs. In it, the conveyor-belt made up of the bottom tape is replaced by a printing head 336 that manufactures the bottom base tape 410 in situ. This simplifying change can be tolerated if the final tissue tape-sandwich still has sufficient strength provided now only by the top tape. The in situ manufactured bottom tape is then only acting as a relief to protect the tissue from friction damage during reel-up operations.

Another alternative embodiment, which is not depicted in the figures, is to forgo cutting viewing holes in the top and/or bottom base tapes within the microtome, and instead, as a later step, etch these holes using an acid to reveal the tissue slices within. If the top and bottom base tapes are made of a solid material (preferably a metal such as copper) and no holes are cut in the microtome in these tapes, then the composite tape sandwich taken-up on the final take-up reel 302 will not be ready for imaging since the tissue slices between the top and bottom tapes will be hidden by the overlying tapes. This tape-sandwich can then be put through an etching machine where a mask is placed around each section of tape covering up all areas of tape except those having tissue directly beneath. Then the tape is exposed to an etchant (acid in the case of metal tapes) that will dissolve the parts of the top and bottom tape directly above and below each tissue slice. The etchant is chosen so as not to damage the delicate tissue slice which is revealed via the etching process. The advantage of this viewing hole etching method is that it allows the blockface taping step to proceed with a solid tape instead of one with viewing holes. This implies that the tissue slice being cut can be supported across its entire width during the cutting procedure.

Yet another embodiment of the present invention is directed to the production and preparation of “tissue tapes” (one or more thin tissue sections or ribbons disposed on a substrate) that may be imaged with a scanning electron microscope (SEM). As discussed above, various embodiments of lathe microtomes may be designed to produce tapes for transmission electron microscope (TEM) imaging; however, according to other embodiments, images may be maintained via an SEM, generally resulting in a significant simplification of the overall process, while obtaining SEM images of sufficient (e.g., equivalent) quality to standard TEM images. In one aspect of this embodiment, tissue tapes prepared and collected via an ATLUM may be used to create UltraThin Section Libraries (UTSLs) that allow for fully automated, time-efficient imaging in the SEM.

In one exemplary TEM implementation described above, the block face was coated continuously with a TEM support film and a metal tape was used to collect the cut sections. This metal tape was later etched with holes to reveal the tissue sections and make them ready for transmission EM imaging. In some instances this may be a complicated process and as such may reduce reliability. In contrast to TEM imaging, in embodiments directed to producing tissue tapes ready for SEM imaging, the automatic lathe microtome process may be improved in one or more of the following ways: SEM imaging eliminates the need to create viewing holes in the tissue tape (either during the collection process or after the tape is collected); SEM imaging eliminates the need for TEM support film; SEM imaging allows use of a (carbon coated) plastic collection tape such as boPET (biaxially-oriented polyethylene terephthalate) as opposed to metal tape (plastic tapes do not wrinkle, are more dimensionally stable, and are in general better suited to the automatic tape collection mechanism of the lathe microtome); SEM imaging allows the entire tissue tape to be imaged (TEM viewing holes left some parts of the tape obscured), which allows for much larger regions of tissue to be imaged; the resulting tissue tapes for SEM imaging are more robust to handling since the ultrathin sections are adhered directly to the surface of a thick plastic tape (unlike lathe microtomes employing TEM imaging, where these ultrathin sections were supported only at their edges).

In addition to these improvements of the collection process, an automatic lathe microtome configured for SEM imaging creates tissue tapes that can be more efficiently imaged. For example, the tissue tapes can be taken off the lathe microtome and immediately stained with heavy metals and SEM imaged, and no other processing may be required.

More specifically, in one exemplary embodiment directed to SEM imaging, the tissue tape is cut into long strips (at points where there is no tissue), and these strips are mounted onto the surface of a thin metal plate. The protective cover tape (which the automatic lathe microtome adheres to the tissue tape during the collection process) is removed and the plate with sections attached is bathed in heavy metal staining solutions. The resulting “tissue plate” is then mounted in an SEM having a stage with large x-y range (like those designed for semiconductor wafer inspection whose stages can accept large wafers up to 300 mm wide). Any point on the plate's surface (i.e. any section of the collected tissue) can thus be electron backscatter imaged within the SEM at resolutions in the nanometer range.

A set of a few dozen tissue plates would constitute an UltraThin Section Library (UTSL), a permanent repository containing the ultrathin sections of a large volume of brain tissue. For example, with 50 nm sections a set of 100 plates would hold up to 50 cubic millimeters of tissue, any point of which could be imaged at nanometer resolution at any time simply by loading the appropriate plate in the SEM. The automatic lathe microtome can quickly create an UTSL of many cubic millimeters of tissue, enough to encompass multiple brain regions and their interconnecting axonal tracts. The UTSL can then be swiftly SEM imaged at intermediate resolution, and this can be used to intelligently direct subsequent (time intensive) high-resolution imaging forays. In this way a researcher can efficiently map out specific neural circuits spanning many millimeters with a resolution in the nanometer range, a feat impossible with any other imaging technology.

More specifically, in one embodiment, an ATLUM directed to SEM imaging produces a continuous ribbon of thin tissue by lathing an extremely thin strip off the surface of a cylindrical block containing one or a multitude of embedded tissue samples. This continuous ribbon of tissue is simultaneously collected onto a plastic support tape by the taping mechanism of the ATLUM and is subsequently reeled up for later heavy metal staining and SEM backscatter imaging of the ultrathin tissue sections it contains.

An exemplary process according to one embodiment starts by mounting the cylindrical tissue block on a metal axle that is held and rotated by a high-precision rotary stage. A diamond ultramicrotome knife (with attached water boat) is driven forward into the rotating block by means of a high-precision linear stage capable of steps on the order of a few nanometers. By synchronizing the rotational speed of the rotary stage with the advancement speed of the knife, the knife's edge is Caused to trace a spiral path through the cylindrical tissue block thus producing a continuous ribbon of tissue of the desired thickness. This process is exactly analogous to a conventional lathe producing a continuous “chip.”

The continuous ribbon of tissue produced in this manner comes streaming off of the knife's edge and flows across the surface of the water in the knife's water boat. The automatic lathe microtome uses a conveyor belt (made of specially coated plastic tape) submerged in the water boat to collect this streaming ribbon of tissue. The conveyor belt is driven such that its collection speed is closely matched to the knife's cutting speed. In this way, the ultrathin ribbon of tissue, which is continuously being produced at the knife's edge, floats for a short time across the water of the knife boat and is quickly collected by the conveyor belt of collection tape.

In the ATLUM, the fragile tissue ribbon is always under complete control of the mechanism, being attached at one end to the block (from which it is being produced) and being attached at the other end to the collection tape (submerged conveyor belt) to which it is being permanently attached for later imaging. The continuous nature of the ATLUM's sectioning and collection process in this embodiment, and its constant control of the fragile ribbon, allows the ATLUM to operate with complete autonomy and with high reliability and to produce larger volumes of ultrathin tissue sections than any previous conventional microtome design.

In one aspect of this embodiment, the ATLUM's tape collection mechanism includes a continuous reel-to-reel mechanism containing a plastic film (tape) coated with carbon, as discussed in further detail below. Part of this tape web is submerged in the knife's water boat in order to collect the tissue ribbon on the tape's carbon-coated surface. Immediately after the ribbon is collected on the collection tape an adhesive cover tape is applied for protection during subsequent handling (this cover tape has adhesive on its sides but not along its center, thus it protects the tissue ribbon without actually coming into contact with it). The final “tissue tape” (carbon-coated plastic film, collected tissue ribbon, and cover tape) is reeled up on a final take-up spool. Recall that all aspects of this collection process are continuous and are synchronized with the continuous cutting process.

The plastic film used in one embodiment for preparation of a tissue tape is boPET, which is strong, does not wrinkle as it goes through the mechanism, has an exceptionally smooth surface, and which has a high degree of dimensional stability. The smooth surface is important for later imaging since the tissue ribbon should lie down as flat as possible on the tape. In some exemplary embodiments directed to SEM imaging, the boPET tape is coated with a layer of carbon (approximately one micron thick) on the side that will pickup the tissue. This carbon coating does three things: 1) it prevents charging in the SEM by providing an electrically conductive path; 2) it prevents electron beam damage by providing an efficient heat conductor under the tissue; and 3) it provides a highly uniform, low density (low z-number) substrate on which the tissue can rest. Since the tissue may be imaged via SEM using backscattered electrons it is important that the substrate itself generate as little interfering backscatter signal as possible and carbon provides this benefit. In other embodiments discussed in greater detail below, a polyimide tape such as Kapton® may be employed as a suitable substrate to facilitate SEM imaging.

Once collected, the tissue tape is cut into long strips (at points where there is no tissue), and these strips are mounted onto the surface of a thin metal plate. The protective cover tape is removed and the plate with sections attached is bathed in heavy metal staining solutions. The solutions (typically uranyl acetate and lead citrate) stain selected biological structures within the sections with heavy (high z-number) atoms producing high electron backscatter signals during subsequent SEM imaging. The resulting “tissue plate” is then mounted in an SEM having a stage with large x-y range and a researcher can subsequently use the SEM to image any point on the tissue plate at high resolution.

A single ATLUM run can potentially produce hundreds of meters of tissue tape from a single biological sample a few tens of cubic millimeters in volume. This extremely long tape can then be used to produce a set of approximately 100 tissue plates. In this way the original biological sample has been reduced to an “UltraThin Section Library” (UTSL). This concept of a UTSL is important to understanding the usefulness of the automatic lathe microtome to researchers. For example, with 50 nm thick sections a set of 100 plates would hold up to 50 cubic millimeters of tissue, any point of which could be imaged at approximately 5 nm in plane resolution at any time simply by loading the appropriate plate into the SEM. At this resolution this UTSL would potentially represent 40,000 terabytes of imaging data. This is an almost unimaginable amount of data to store and process and the SEM imaging time required to image the entire UTSL is on the order of centuries. However, the UTSL itself is quite compact (just one hundred plates) and any point within this massive data set can be imaged at will by simply loading (e.g., manually or robotically) the corresponding tissue plate into an SEM.

The ability to efficiently direct nanometer resolution imaging anywhere within a volume of many cubic millimeters of biological tissue is exactly what neuroscience researchers require to map the circuits of the brain. A typical neural circuit includes, several interconnected neurons each sending long thin axonal processes many millimeters into separate brain regions. These axonal processes subsequently branch out and make synaptic contacts within these regions that can only be seen with nanometer resolution imaging. Thus neuroscientists are faced with the significant challenge of producing nanometer resolution volume images of large volumes. The UTSL allows just that. The neuroscientist researcher can produce a UTSL containing the brain regions and connecting axonal pathways they wish to study. The researcher can then intelligently direct the SEM to image just those regions within the massive volume that are needed to trace out the circuit of interest. Since the UTSL is a permanent repository of this neural volume, this or another researcher could easily follow-up on the original circuit study by tracing additional branches of the very same neurons. In this way a single UTSL could allow a whole set of collaborative circuits mapping studies over a series of years, potentially revealing the complicated web of neural circuits the brain uses to perceive, remember, reason about, and purposefully act upon the world.

Another embodiment of the present invention is directed to closed-loop feedback control in an ATLUM to regulate thickness of thin tissue sections or ribbons sliced from a block or bulk tissue sample. As described above, conventional microtomes typically move a tissue block along a linear path past a knife edge to produce a section, and then retract the knife during a reset phase in preparation for the next section. For a lathe microtome, operation may be more continuous without need for knife retraction. A tissue block may be mounted on an axle which may be rotated such that the tissue traces a circular path around the rotational axis in close proximity to an advancing knife. As the tissue block moves along its circular path, it may intersect the knife edge, allowing a section to be sliced off in the process. In various embodiments of the ATLUM design, sectioning performance may be improved, along with allowing thinner sectioning below 40 nm thick with greater reliability and uniformity. The tissue sample to be sectioned may be embedded in and/or around a smooth axle and mounted on a rotary stage of the ATLUM. Capacitive sensors may be used to precisely measure the distance between the knife edge and the axle surface. This distance measurement may be fed back to the knife stage via, but not limited to, an analog PID controller which endeavors to maintain a target distance from the knife edge to the axle surface. In this manner, variable forces, encountered at the knife edge during sectioning that would normally produce section thickness variations may be compensated in real time via closed-loop feedback control.

When attempting to cut very thin sections, it is advantageous to reduce section thickness variations where possible. For example, if a user were attempting to section at 40 nm thickness and a variability of +/−20 nm exists in the knife edge position relative to the block, then one may cut 20 nm too thick on a part of the Nth section and 20 nm too thin on the (N+1)th section. These two errors would combine to reduce a part of the (N+1)th section to zero thickness, leading to a break. Such breaks, if they occur often enough, may be problematic for automatic collection of sections.

To address the foregoing, according to one embodiment of the present invention one or more capacitive sensors mounted to the knife stage and positioned so as to effectively measuring the distance from the knife edge to the rotating steel axle containing the tissue block may allow for the knife edge to be stabilized during sectioning to vary significantly less than +/−20 nm. In some embodiments, knife edge stabilization may occur during sectioning such that section thickness variations are less than +/−10 nm. In further embodiments, knife edge stabilization may occur during sectioning such that section thickness variations are less than +/−5 nm. In even more embodiments, knife edge stabilization may occur during sectioning such that section thickness variations are less than +/−1 nm. Once section thickness variation is suitably limited, reliable sectioning may occur to thicknesses less than 40 nm and lengths greater than 5 mm. From aspects presented herein, collection of hundreds of large area sections at thicknesses at or below 50 nm may occur for large volume electron microscopic reconstructions of brain tissue.

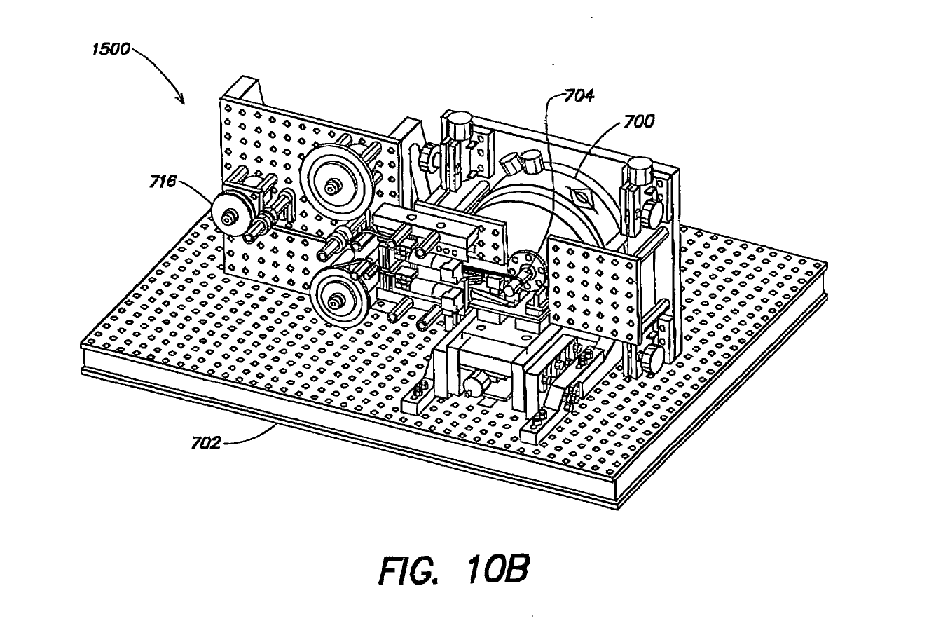

Various aspects of an ATLUM configured with closed-loop feedback control of sliced tissue thickness based on a capacitive sensing technique are discussed in further detail below in connection with FIGS. 10-15. For example, FIG. 10A shows a front plan view of an ATLUM 1500 and FIG. 10B shows a perspective view of the same ATLUM 1500 according to one embodiment of the present invention in which closed-loop feedback control is implemented. In the figures, an air bearing rotary stage 700 may be securely mounted to an optical table 702 floated on air for vibration isolation. A steel axle 704 with a tissue sample may be mounted in the rotary stage 700 via a collet chuck. In some embodiments, the steel axle 704 may have a 0.5 inch diameter. In other embodiments, the steel axle 704 may have a diameter greater than 1 inch. A diamond knife stage 708 allows for the rotating block of tissue sample to be sectioned or sliced upon contact with a knife edge, and a conveyor belt collection mechanism 710 allows these sections to be automatically collected on a substrate (or “support film”) supplied by feed reel 712 to form a “tissue tape.” This tissue tape may be temporarily sealed with a protective top tape supplied by feed reel 714, and the assembly of substrate, sliced thin tissue, and protective top tape may be collected on the final take up reel 716. After completion of a run, tape collected of ultrathin sections may be stained with heavy metals and imaged in a SEM using an electron backscatter signal, as discussed above, to produce high-quality, high-resolution images of the tissue's ultrastructure (e.g., sufficient for mapping the synaptic connectivity of brain tissue). It should be understood that in the embodiment shown, any suitable type of thin tissue section(s) or ribbon(s) may be produced. Tissue samples may be prepared for slicing in any appropriate manner as well, such as through embedding, as described previously. In various embodiments, a tissue sample may be mounted on a rotatable axle 704 for slicing by placing a round block that contains tissue to be sectioned around the axle 704. In further embodiments, a tissue sample may be mounted on a rotatable axle 704 for slicing by placing a block of any shape into a receiving portion of the axle 704 which may be rotated such that the top of the block may be appropriately sliced by the knife edge with each revolution of the rotatable axle 704. As discussed further below, the tissue samples mounted to the axle 704 may be cylindrical in nature, or have wedge-like geometries.

In one embodiment, the substrate supplied by feed reel 712 may exhibit qualities that enable the thin tissue sections mounted thereon to be imaged effectively using SEM techniques. In SEM, several high-voltage electrons (˜10 kV) in an incident imaging beam typically pass through the thinly sliced tissue and interact with the substrate/support film underneath the tissue. If the support film degrades due to excessive electron exposure during imaging, the tissue above it will likely degrade also. In this regard, one salient characteristic of a substrate suitable for use in SEM imaging of thinly sliced tissue includes resistance to bombardment with radiation and/or electrons. Another salient characteristic of a substrate suitable for use in SEM imaging of tissue sections includes a relatively high resistance to heat. In this respect, an exemplary suitable substrate has a high melting point relative to local temperatures found during SEM imaging and/or the ability to conduct heat so that tissue is not exposed to high temperatures for extended periods of time. Material containing atoms with low Z-number and atomic weight, providing little intrinsic backscatter signal so as to not interfere with SEM and/or backscattered electron imaging, also provide a suitable substrate for SEM imaging of the thinly sliced tissue.

In some embodiments, as discussed above, the substrate upon which thin tissue sections are mounted may be boPET (e.g., Mylar). In further embodiments, so that the substrate exhibits a greater degree of conductivity, substrates may incorporate a carbon additive in any suitable form, such as, for example, in an extra layer deposited on the top and/or bottom of the substrate. In other embodiments, the substrate upon which thin tissue sections are mounted may be polyimide (e.g., Kapton® produced by DuPont™). Kapton® remains stable at temperatures up to 400 degrees Celsius and has excellent radiation resistance as well. In various embodiments, thin tissue sections may be collected directly on the surface of bare Kapton® (without a previous carbon coat) and subsequently a very thin layer (˜10 nm) of carbon may be deposited on top of the tissue for charge dissipation purposes. In this respect, this tissue section thusly prepared may facilitate sufficient quality high-resolution SEM images of the tissue while appearing to withstand multiple, high-current image captures without damage to the tissue. In addition, use of bare or lightly carbon coated Kapton® makes the feed substrate materials for the ATLUM machine less expensive, avoiding depositing a thick carbon coat (˜1 micron thick) onto the long collection tape, which can be an expensive procedure. In general, users of an ATLUM-created UTSL may often require that the same region of a section be imaged multiple times, for example when conducting multiscale imaging or collecting a scanning electron tomographic tilt series. In this regard, collection of tissue on bare or lightly carbon coated Kapton® facilitates repetitive high resolution imaging.

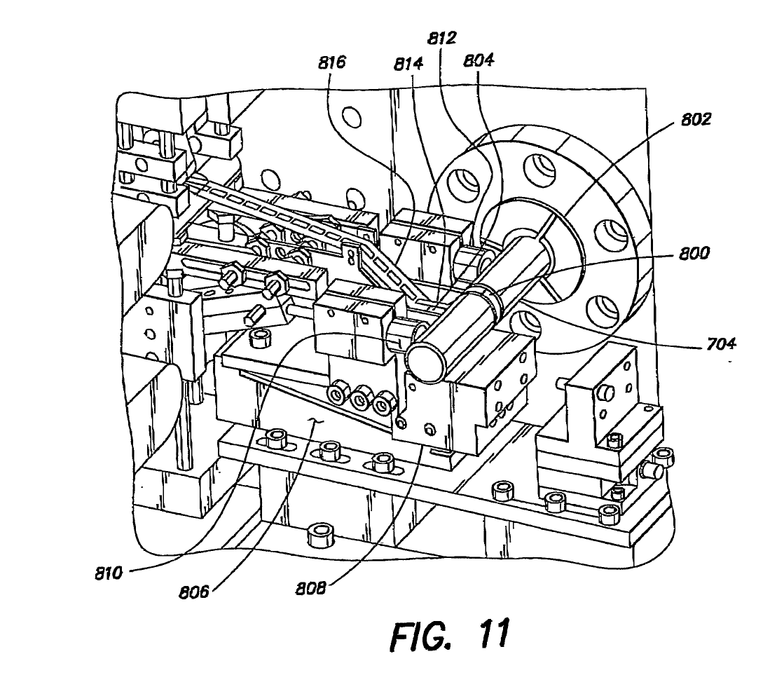

FIG. 11 shows a closer view of the knife stage, tissue axle, and conveyor belt collection mechanism. A wedge-shaped tissue sample 800 may be mounted on the rotatable axle 704, which may, as discussed above, be mounted in the rotary stage via a collet chuck 802. A diamond ultramicrotome knife 804 may be attached to a piezo tilt stage 806 via a mounting bracket 808. Mounting bracket 808 may also hold a pair of capacitive sensors 810 and 812. These capacitive sensors 810 and 812 may be mounted at essentially the same height as the ultramicrotome knife 804 edge, and configured to measure a distance between the knife edge and the surface of the steel axle 704. Capacitive sensors 810 and 812 may be mounted on either side of the knife, and thus their averaged distance measurement can effectively measure the distance of the knife edge to the axle surface (with some absolute offset). This averaging of symmetrically mounted sensors can produce a distance measurement that may compensate for any wobble of the axle during its rotation. It should be understood that any appropriate type and number of sensors may be used to measure the distance between knife edge and the steel axle 704. Indeed, it is possible for only one sensor to be used in measuring this distance. The sensor may function in any suitable manner, one example being through a capacitive sensing system. As a result, from knowing the rate at which the knife edge moves towards the steel axle 704 and the rotational velocity of the tissue block around the steel axle 704, the thickness of the resulting sliced tissue section may be suitably estimated. Floating tissue section 814 may be collected from a water boat positioned along with the knife 804 via a partially submerged conveyor belt 816 or any other appropriate method.

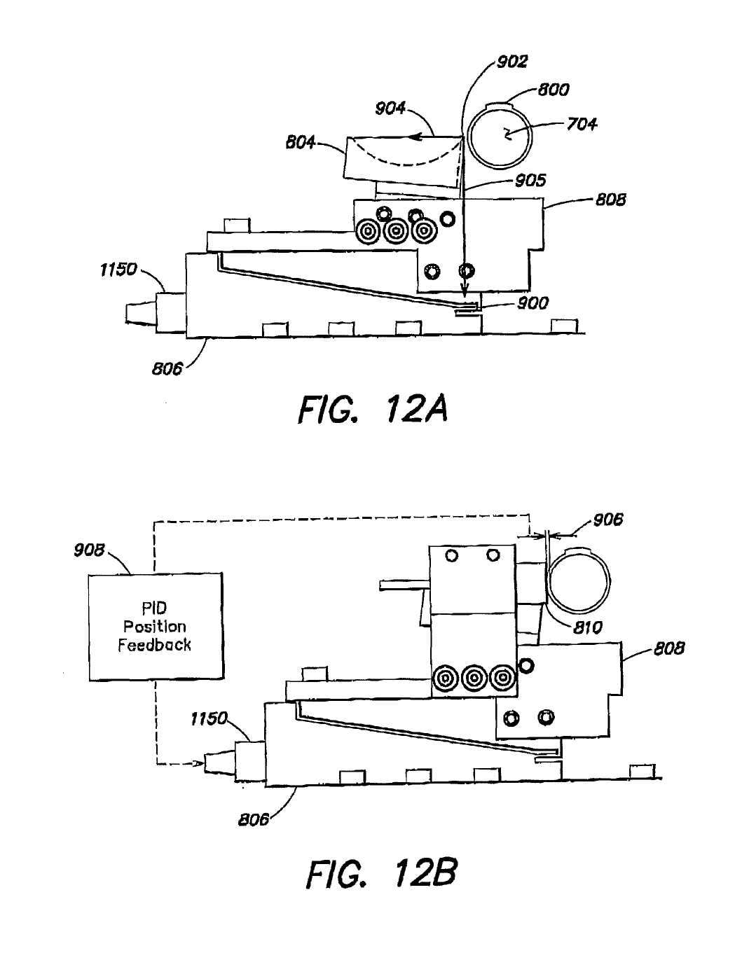

FIG. 12A shows the piezo tilt stage 806 from a side plan view with sensors 810 and 812 removed in this view for clarity. A fulcrum 900 of the tilt stage 806 may be positioned directly below the edge of the knife 804. In this respect, the largest cutting forces may be absorbed by the stiffest part of tilt stage 806. When a linear piezo actuator within tilt stage 806 expands it causes the knife to rotate forward around fulcrum point 900. This tilt causes the knife edge 902 to move forward toward axle 704 and to cut off a section of tissue wedge 800 as the axle 704 rotates.

As mentioned above, in one aspect, the tilt stage 806 compensates for variable forces encountered during sectioning. The greatest force on the knife 804 during sectioning is often the force that occurs in the direction that the knife is plowing through the tissue, which force is depicted in FIG. 12A by force vector 905. In various embodiments, the fulcrum point 900 may be placed directly in line with this force component, reducing torque that may arise which also could move the knife. Smaller forces applied to the knife edge in the direction depicted by force vector 904 may occur during sectioning as well, giving rise to a likelihood for the knife to move away from the axle due to the stage's finite tilt stiffness and due to the stage's finite x-stiffness (x direction parallel to arrow 904). In one aspect, the tilt stage 806 may be piezo actuated, allowing for ˜5 nm positioning resolution of the knife edge. In this regard, due to construction of the piezo tilt stage, tilt stiffness and x-stiffness may both be coupled to the piezo actuator and may thus be compensated. When using capacitive feedback (e.g., via the capactive sensors 810 and 812), an integral control term may effectively provide infinite stiffness, limited by bandwidth, to the piezo actuator. As the tilt stage may couple forces at the knife edge to the piezo actuator, the knife edge may be effectively rigid relative to the axle 704 surface, allowing for reductions in section thickness variations such that large block faces may be sectioned at thicknesses at or below 50 nm. It should be understood that any suitable actuation mechanism may be incorporated in operation of the tilt stage, including, but not limited to, piezo actuation, electromechanical actuation, or any other appropriate method.

It is noted that as a result of use of a tilt stage, as the knife advances during a run, the clearance angle of the knife may change. In some instances, changing clearance angle may be problematic if the clearance angle were to change drastically; however, in the embodiment depicted in FIGS. 11 and 12, the clearance angle may change by only a fraction of a degree over the full range of knife travel, which may be approximately ˜300 microns.

FIG. 12B shows the piezo tilt stage 806 from a side plan view with capacitive sensor 810 also shown. The distance that the sensors 810 and 812 are measuring is depicted by dimension 906. This distance may be tightly controlled by a controller 908 which drives the piezo actuator in tilt stage 806. In some embodiments, the controller 908 may be a proportional-integral-derivative controller or any other suitable feedback controlling device.

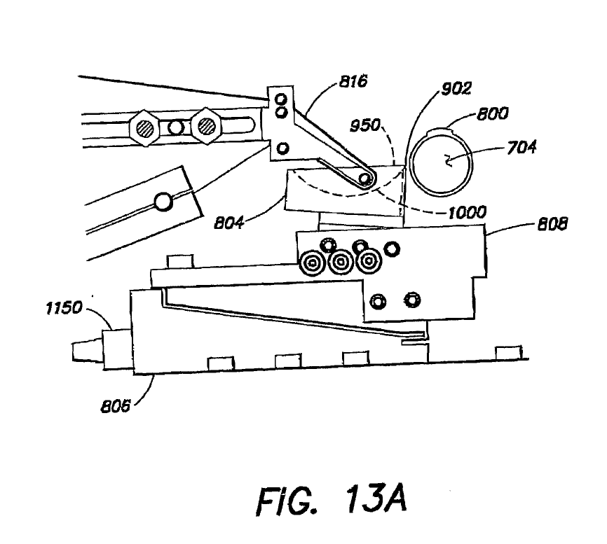

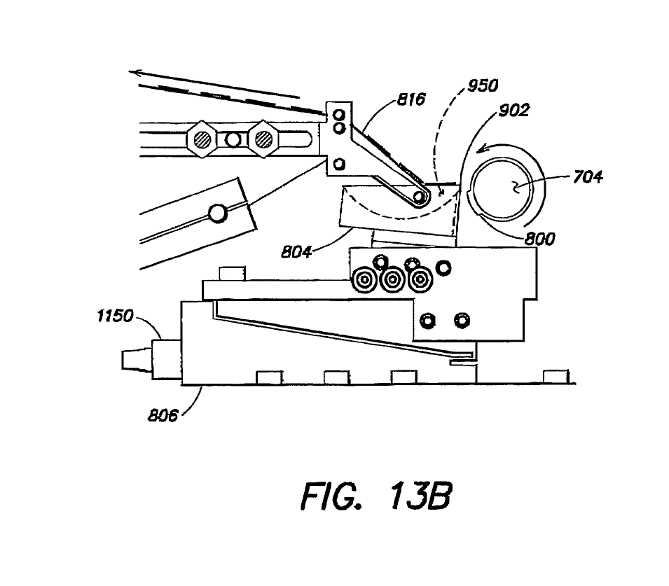

FIG. 13A shows another close-up side view of the piezo tilt stage 806 shown in FIGS. 11 and 12, further illustrating the conveyor belt 816 partially submerged in the water of a water boat 950 behind the edge 902 of knife 804. The water boat may be incorporated directly behind the knife edge such that the surface tension of the water may support the fragile thin tissue section as it is being sliced from the tissue sample 800 on the rotatable axle 704. The surface tension may provide a suitable frictionless support for the thin tissue section, allowing it to stream smoothly off the knife edge. The submerged conveyor belt 816 may also be provided in the water boat close to the knife edge running at a similar speed to that of the tissue sections streaming off the knife edge. In this manner, each tissue section may be gently collected onto the surface of the conveyor belt. The curved bottom 1000 of the water boat 950 is depicted with a dashed line to show how conveyor belt 816 dips into the water but does not scrape the bottom 1000 of the water boat. In this respect, the angle that the edge of the water boat makes with a tangent of the steel axle 704 at the point of slicing may be relatively coincident so that a thin tissue section may come off the axle 704 smoothly and into the water boat. In one embodiment of operation, FIG. 13B shows a tissue block with a protruding tissue wedge 800 mounted on to the steel axle 704 that rotates in proximity to the knife 804. In this example, once the tissue wedge 800 rotates into the knife edge, a thin tissue section may be smoothly sliced off on to the water surface of the water boat. The thin tissue section may then, migrate towards the conveyor belt 816 which takes up the thin tissue section for further processing.

In another aspect of the present invention, lathe microtomes may section cylindrical blocks of tissue sample, wedge shaped blocks (which are partial cylinders that do not extend all the way around the rotary axle), or any other shape that may be suitably sectioned. When sectioning a cylindrical block of tissue sample, the knife smoothly advances while the block is rotated. The knife does not disengage from the block of tissue sample and traces a spiral path through the cylindrical block, producing a continuous ribbon of thinly sliced tissue. This process is similar to how a rotary lathe cuts continuous wood veneers by rotating a log past a very wide knife edge. When sectioning a wedge shaped block of tissue sample for a desired section thickness, the knife may be stepped forward once per revolution during the part of the rotation cycle when the tissue wedge is not being cut by the knife. The knife may then be left in place or may move only slightly forward during the part of the rotation cycle when the knife is sectioning the wedge. In these block sectioning modes, rotational motion of the lathe is not required to reverse direction, and knife motion is not required to retract, typically moving forward into the block. In this respect, such attributes, including having stable cutting performance, make lathe microtomes appropriate for automated section collection techniques.

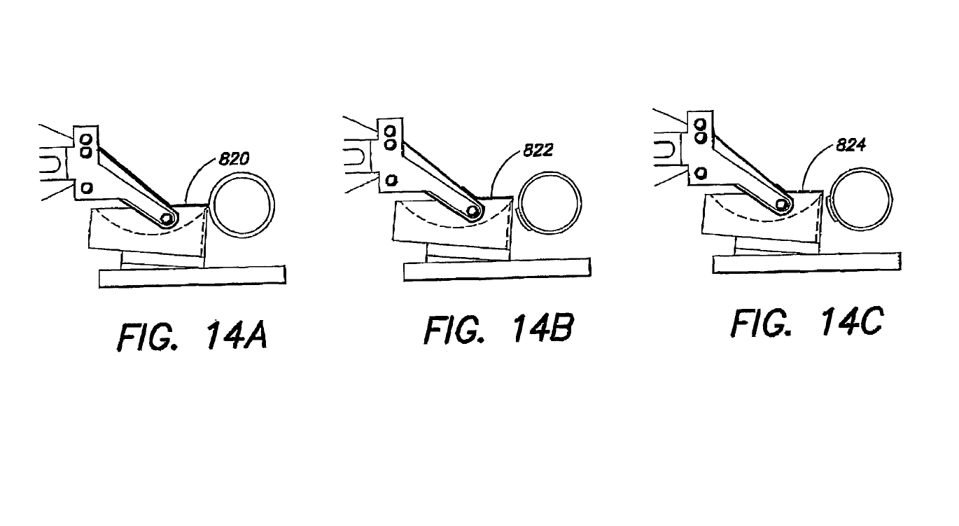

In different embodiments presented herein, if a continuous ribbon 820 of tissue is being sectioned from a full cylindrical block of tissue sample, as shown in FIG. 14A, then the ribbon 820 may extend from the knife edge, across the water boat for a few millimeters, and to the conveyor belt, where the ribbon 820 may be continuously collected. In this regard, the conveyor belt collection speed should be well matched to the sectioning speed.

In other embodiments, if a partial cylinder block, or wedge of tissue sample, is being sectioned then it should be considered whether the thin sliced tissue section has a relatively longer length 822, i.e., longer than the distance from the knife edge to the conveyor belt, as shown in FIG. 14B, or whether the sliced tissue section has a relatively shorter section length 824, i.e., shorter than the distance from the knife edge to the conveyor belt, as shown in FIG. 14C. In both of these cases each section may be momentarily secured only at the knife edge while the leading edge of the section is pushed toward the conveyor belt by the momentum of the rest of the section being created behind it. For section lengths 822 that are longer than the distance from the knife edge to the conveyor belt, in order to minimize the tendency for the thin tissue section to bend on its way to the conveyor belt, it may be beneficial for the knife edge to be accurately adjusted so that it is relatively parallel to the tangent of the rotational axis of the lathe at the point of contact. To further minimize tendencies for the thin tissue section to bend on its way to the conveyor belt, the section width may be relatively wide compared to the distance from the knife edge to the conveyor belt. As an example, for a 7 mm distance from the knife edge to the conveyor belt, a section width of 1-2 mm may be used. Further, for reliable collection and full automation to be achieved, the conveyor belt collection speed should be well matched to the sectioning speed.

If the section length 824 is shorter than the distance from the knife edge to the conveyor belt, as shown in FIG. 14C, the sections can still be collected reliably and automatically, where the Nth section may simply be pushed toward the conveyor belt by the (N+1)th section. In this respect, the leading and trailing edges of each section should be relatively straight to prevent the free Nth section from being pushed at an angle by the (N+1)th section. This condition may be met by being sure that the wedge shaped block of tissue sample is shaped such that the leading and trailing edges are substantially parallel to the knife edge. Also, for a greater degree of collection reliability and ability for full automation to be achieved, the knife edge may be accurately adjusted so that it is relatively parallel to the tangent of the rotational axis of the lathe at the point of contact. In addition, the section width may be relatively wide compared to the distance from the knife edge to the conveyor belt. For the case where the section length is shorter than the distance from the knife edge to the conveyor belt, it should be noted that it is not necessary for the conveyor belt collection speed to be well matched to the sectioning speed, but the conveyor belt collection speed should be fast enough to ensure that sections do not bunch up in the water boat.

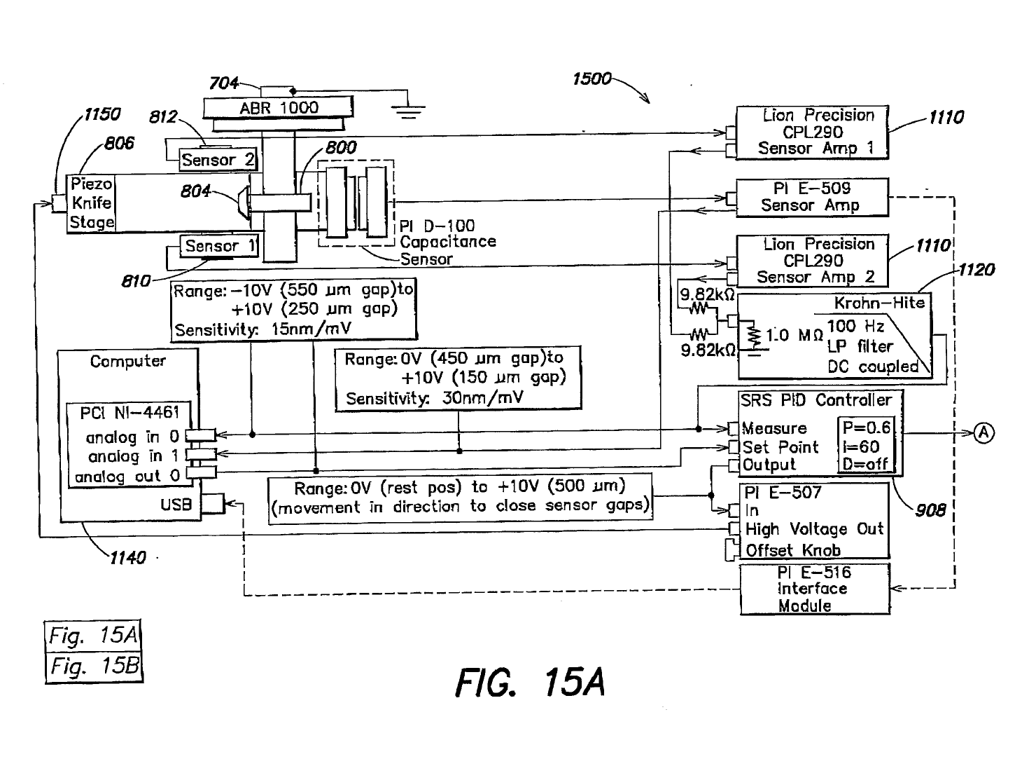

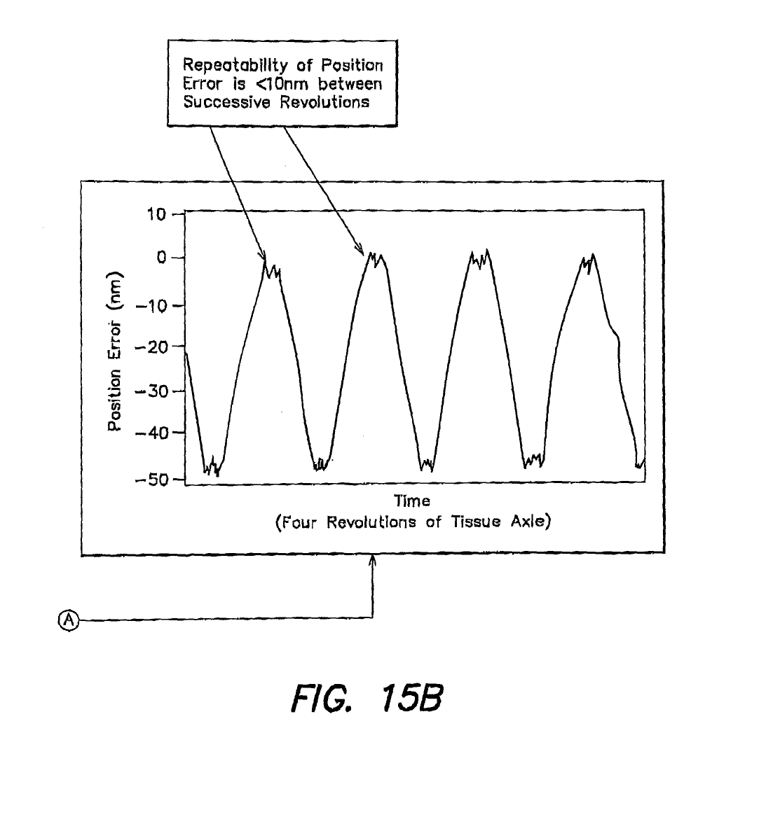

In accordance with other aspects of the present invention, FIG. 15 depicts an embodiment of an electronics diagram for capacitive feedback control of the piezo knife stage implemented on the ATLUM. It should be understood that any appropriate capacitive feedback control mechanism may be used for suitable sectioning to occur. In this embodiment, sensor 1 810 and sensor 2 812 are capacitive sensors placed on either side of the microtome knife 804. These sensors measure distance to the surface of the rotating steel axle, which is grounded, and upon which the tissue sample 800 to be sliced is disposed. Each sensor's capacitance may be accurately measured and converted to a voltage via CPL290 sensor amplifiers (from Lion Precision) 1110. These twin voltages may then be averaged via a resistive summing circuit 1120 and low pass filtered to generate a measurement signal that represents a single virtual sensor located equidistant between the two actual sensors and coincident with the knife 804. This single averaged measurement signal may then be fed to an analog PID controller 908 where it may be compared to a setpoint voltage generated by a control computer 1140. In some embodiments, this setpoint voltage is generated by a National Instruments PCI-4461 board with a 24 bit precision digital to analog converter. The error signal from the PID controller 1130 may be monitored via the computer 1140 and via an external oscilloscope during each ATLUM run to watch for signs of knife chatter, which may be seen in the oscilloscope trace if present. As a result, cutting parameters such as speed may be adjusted in order to eliminate chatter. The output of the PID controller 1130 may be fed (e.g., via a high voltage amplifier) to a high-voltage piezo actuator 1150 which controls movements of the tilt stage 806, thereby completing the feedback control loop. It should be appreciated that in other embodiments, the functionality of one or more of the controller 908, the computer 1140, the sensor amplifiers 1110, summing circuit and low pass filter 1120 may be combined in a single controller to implement the feedback control.

In traditional ultramicrotomes which do not employ closed loop position control of the knife, several factors may contribute to section thickness variations when cutting sections. These factors may include temperature fluctuations, non-uniform cutting forces during sectioning, and external vibrations. The magnitude of the section thickness variations caused by these factors is roughly proportional to the “path length” from the knife to the block. For example, in a traditional ultramicrotome, the knife is mounted on top of stages for fine adjustment of clearance angle and yaw adjust which are secured to the microtome base, whereas the tissue block is held by a specimen arm and movement mechanism that is secured to the microtome base. The total length of this mechanical path, from the knife edge to the tissue block, may amount to almost half of a meter. Any thermal differentials will operate over this full length to cause a discrepancy between the desired knife position and the actual knife position. Similarly, any non-uniform cutting forces or external forces due to vibrations will operate over the flexibility inherent in this full path length. One advantage of including capacitive closed loop control in the ATLUM is in effectively reducing this “path length” to only a few centimeters since the controller 908 maintains the distance from the sensors to the surface of the rotatable axle 704 essentially constant, the sensors are secured only a centimeter away from the knife itself, and the tissue sample block is secured to the surface of the rotatable axle only a centimeter away from where the capacitive sensors are sensing. In addition, closed loop position control allows for the ability to monitor nanoscopic variations of knife position in real time during a run allowing chatter to be immediately identified, quantified, and compensated.

Another embodiment of the present invention is directed to implementing continuous closed-loop control of section thickness in an automatic lathe microtomes (ATLUM) as discussed above by video microscope monitoring of section interference color and other means. In one aspect of this embodiment, automatic lathe microtomes operate more reliably and to produce thinner sections having tightly controlled thickness, all of which are crucial to high quality volume reconstructions of biological samples.

In an exemplary embodiment directed to closed-loop control, one or more characteristic colors of thin samples are employed as a feedback parameter. For example, with proper lighting, illumination and viewing angles, sections of thicknesses less than one micron have a characteristic color. This color arises because light reflecting from the top of the section and light reflecting from the bottom of the section have been shifted out of phase with respect to each other by an amount dependent on the wavelength of the incident light and the section thickness. Depending on the accumulated phase difference, either constructive or destructive interference will occur. If a white light is used as the source illuminant, then some wavelengths present in the white light will be enhanced while others will be diminished. The resulting modified continuous spectrum appears to humans (with our tricromatic visual systems) as a color change (and/or brightness change, hereafter simply referred to together as a ‘color’ change). This color change is quite easily observed and measured, and can be directly related back to absolute thickness of the section.

There are, in principle, many ways to automate the monitoring of this interference effect. In one exemplary implementation, several selected wavelengths of illumination are used and several light sensors tuned to particular spectral locations are chosen for optimal discrimination of section thickness in the particular range of thicknesses for which the lathe microtome is designed to cut (a typical range is 150 nm to 20 nm). One way of achieving this automatic process monitoring is to tap into the color video signal of the lathe microtome's video microscope which is already used to monitor the continuous ribbon of tissue sections coming off the knife edge of the lathe microtome into the water boat. The respective RGB (red-green-blue) values of a small window of the video (focused on the ribbon just as it leaves the knife edge) can then be recorded and compared to a stored lookup table of calibrated RGB-to-thickness values. The result is a single number, a continuous estimate of the instantaneous section thickness. If the measured thickness does not equal the desired cutting thickness (due to thermal drift etc.) the difference error can be fed back to the knife's advance speed controller. For example, if 50 nm thickness was desired but the video estimated current 40 nm thickness, the speed of the knife's advance could be automatically slowed slightly to prevent cutting too thinly (which may result in section breakage).

The monitoring of section interference color described above is but one technique of providing the process feedback for closed-loop control of section thickness in an ATLUM according to the present invention. In another embodiment directed to closed-loop control, a direct measurement of the block face's radial distance (distance from the block's axis of rotation) may be employed as a feedback parameter. For example, in one embodiment, an ultralight direct-contact stylus (like those used in atomic force microscopy) can be positioned to drag on the block face at a point just ahead of the knife. This stylus would measure the thickness of each point on the cylindrical block a few seconds prior to that point being sectioned. By knowing the rotational speed of the block and the positional lag of the stylus, a closed-loop controller may adjust the knife position in anticipation of each point's out-of-roundness error and thus reduce this error, producing a continuous ribbon of constant thickness.

Having thus described various illustrative embodiments, it is to be appreciated that various alterations, modifications, and improvements will readily occur to those skilled in the art. Such alterations, modifications, and improvements are intended to be part of this invention, and are intended to be within the spirit and scope of this invention. While some examples presented herein involve specific combinations of functions or structural elements, it should be understood that those functions and elements may be combined in other ways according to the present invention to accomplish the same or different objectives. In particular, acts, elements, and features discussed in connection with one embodiment are not intended to be excluded from similar or other roles in other embodiments. Accordingly, the foregoing description and attached drawings are by way of example only, and are not intended to be limiting.

1. A method for preparing and imaging a tissue sample, the method comprising:
A) slicing the tissue sample into at least one thin tissue section;
B) mounting the at least one thin tissue section on to a substrate, the substrate comprising a conductive material; and
C) imaging the mounted at least one thin tissue section with a scanning electron microscope.

2. The method of claim 1, further comprising performing A) and B) automatically.

3. The method of claim 1, further comprising bathing the at least one thin tissue section in a heavy metal staining solution prior to C).

4. The method of claim 1, wherein B) comprises using an adhesive to affix at least one portion of the thin tissue section to the substrate.

5. The method of claim 1, further comprising storing the mounted at least one thin tissue section for imaging at a later time.

6. The method of claim 1, wherein C) comprises imaging back scattered electrons.

7. The method of claim 1, wherein A) comprises slicing the tissue section to a thickness of less than 50 nanometers to form the at least one thin tissue section.

8. The method of claim 1, wherein the tissue sample comprises a substantially cylindrical tissue block, wherein A) comprises slicing the substantially cylindrical tissue block into a thin tissue ribbon, and wherein B) comprises mounting the thin tissue ribbon on to the substrate.

9. The method of claim 1, wherein A) comprises implementing a closed loop feedback system for controlling a thickness of the at least one thin tissue section.

10. A tissue sample prepared for scanning electron microscopy imaging, the tissue sample comprising:
a substrate comprising a conductive material; and
at least one tissue section mounted on to the substrate, the at least one tissue section having a section thickness, the section thickness being less than 500 nanometers.

11. The tissue sample of claim 10, wherein the section thickness is less than 150 nanometers.

12. The tissue sample of claim 10, wherein the section thickness is less than 50 nanometers.

13. The tissue sample of claim 10, wherein the substrate comprises a carbon layer in contact with the substrate.

14. The tissue sample of claim 10, wherein the substrate comprises biaxially oriented polyethylene terephthalate.

15. The tissue sample of claim 10, wherein the substrate comprises polyimide.

16. The tissue sample of claim 15, wherein the tissue sample comprises neural tissue.

17. The tissue sample of claim 10, wherein the tissue sample comprises neural tissue.

18. A method for preparing a tissue sample, the method comprising:
A) slicing the tissue sample in a slicing direction using a microtome knife to provide at least one thin tissue section, the at least one thin tissue section having a section thickness, the section thickness being controlled by an advancement of the microtome knife into the tissue sample in a substantially perpendicular direction relative to the slicing direction;
B) monitoring the advancement of the microtome knife into the tissue sample as the tissue sample is being sliced to provide an estimated section thickness;
C) comparing the estimated section thickness to a desired thickness; and
D) controlling the advancement of the microtome knife into the tissue sample so that a difference between the estimated section thickness and the desired thickness is less than or equal to 20 nanometers.

19. The method of claim 18, wherein B) comprises monitoring an output of at least one capacitive sensor disposed with respect to the microtome knife so as to measure a distance between the microtome knife and a fixed reference point.

20. The method of claim 18, wherein the tissue sample comprises a substantially cylindrical tissue block, and wherein A) comprises slicing the substantially cylindrical tissue block into a thin tissue ribbon having the section thickness.

21. The method of claim 20, wherein slicing the substantially cylindrical tissue block into a thin tissue ribbon comprises rotating the substantially cylindrical tissue block around an axle.

22. The method of claim 21, wherein B) comprises measuring a distance between the microtome knife and the axle.

23. The method of claim 18, wherein D) comprises controlling the advancement of the microtome knife into the tissue sample so the difference between the estimated section thickness and the desired thickness is less than or equal to 10 nanometers.

24. The method of claim 18, wherein A) comprises controlling a piezo tilt stage so as to advance the microtome knife into the tissue sample.

25. The method of claim 18, wherein D) comprises implementing an analog feedback loop to maintain a desired distance between the microtome knife and a fixed reference point.

26. A method for preparing a tissue sample, the method comprising:
A) slicing the tissue sample into at least one thin tissue section, the at least one thin tissue section having a section thickness;
B) monitoring at least one parameter representing the section thickness of the at least one thin tissue section as the tissue sample is sliced to provide an estimated section thickness;
C) comparing the estimated section thickness to a desired thickness; and
D) controlling slicing the tissue sample into at least one thin tissue section, the at least one thin tissue section having a section thickness such that a difference between the estimated section thickness and the desired thickness is less than or equal to 20 nanometers.

27. The method of claim 26, wherein B) comprises monitoring a phase difference output from light reflected off of a top portion of the at least one thin tissue section and a bottom portion of the at least one thin tissue section using at least one optical sensor.

28. The method of claim 26, wherein A) comprises slicing a substantially cylindrical tissue block into the at least one thin tissue section.

29. The method of claim 28, wherein B) comprises monitoring a topography of the substantially cylindrical tissue block prior to slicing using a stylus.

30. The method of claim 28, wherein B) comprises measuring a distance between an axis of rotation of the substantially cylindrical tissue block and a surface of the substantially cylindrical tissue block.

31. The method of claim 26, wherein D) comprises controlling slicing the tissue sample into at least one thin tissue section, the at least one thin tissue section having a section thickness such that a difference between the estimated section thickness and the desired thickness is less than or equal to 10 nanometers.

32. The method of claim 26, wherein A) comprises slicing neural tissue.

33. A microtome system comprising:
a rotatable axle adapted to support at least one tissue sample;
a moveable stage disposed in proximity to the rotatable axle;
a microtome knife coupled to the moveable stage, the moveable stage adapted to position the microtome knife with respect to the rotatable axle so as to provide a first variable distance between the microtome knife and the rotatable axle;
at least one sensor, the at least one sensor adapted to measure the variable distance between the microtome knife and the rotatable axle and provide at least one measurement signal; and
a controller coupled to the moveable stage and the at least one sensor, the controller configured to monitor the at least one measurement signal and control the moveable stage so as to control the variable distance between the microtome knife and the rotatable axle based at least in part on the at least one measurement signal.

34. The microtome system of claim 33, wherein the at least one sensor comprises at least one capacitive sensor.

35. The microtome system of claim 34, wherein the at least one capacitive sensor comprises two capacitive sensors coupled to the moveable stage and disposed on either side of the microtome knife.

36. The microtome system of claim 33, wherein the controller comprises an analog proportional-integral-derivative controller (PID) controller.

37. The microtome system of claim 33, wherein the moveable stage comprises a piezo tilt stage.

38. The microtome system of claim 33, further comprising a substrate conveyor belt disposed adjacent to the microtome knife, the substrate conveyor belt adapted to receive tissue sections sliced from the at least one tissue sample by the microtome knife.

39. A method for preparing and imaging tissue samples, the method comprising:
A) slicing the tissue sample in a slicing direction using a microtome knife to provide at least one thin tissue section, the at least one thin tissue section having a section thickness, the section thickness being controlled by an advancement of the microtome knife into the tissue sample in a substantially perpendicular direction relative to the slicing direction;
B) monitoring the advancement of the microtome knife into the tissue sample as the tissue sample is being sliced to provide an estimated section thickness;
C) comparing the estimated section thickness to a desired thickness;
D) controlling the advancement of the microtome knife into the tissue sample so that a difference between the estimated section thickness and the desired thickness is less than or equal to 20 nanometers;
E) mounting the at least one thin tissue section on to a substrate, the substrate comprising a conductive material; and
F) imaging the mounted at least one thin tissue section with a scanning electron microscope.
